(19) United States
(12) Patent Application Publication
(10) Pub. No.: US 2026/0324267 A1
(43) Pub. Date: Oct. 15, 2026

(54) DISPLAY DEVICE AND ELECTRONIC DEVICE INCLUDING THE SAME

(71) Applicant: Samsung Display Co., Ltd., Yongin-si (KR)

(72) Inventors: Taeyoung SONG, Yongin-si (KR); Wonsuk CHOI, Yongin-si (KR); Taehoon KIM, Yongin-si (KR); Beomyeol PARK, Yongin-si (KR)

(73) Assignee: Samsung Display Co., Ltd., Yongin-si (KR)

(21) Appl. No.: 19/439,971

(22) Filed: Jan. 5, 2026

(30) Foreign Application Priority Data
Apr. 14, 2025 (KR) 10-2025-0048425

(51) Int. Cl. H10K 59/80

(52) U.S. Cl. CPC H10K 59/879; H10K 59/8792

(57) ABSTRACT

A display device may include: a first light-emitting layer on a substrate; a second light-emitting layer on the substrate, and spaced apart from the first light-emitting layer in a first direction; a first lens overlapping with the first light-emitting layer, on the first light-emitting layer, the first lens including a first radius of curvature; and a second lens overlapping with the second light-emitting layer, on the second light-emitting layer, the second lens including a second radius of curvature that is smaller than the first radius of curvature.

### CROSS-REFERENCE TO RELATED APPLICATION

This application claims priority under 35 USC § 119 to Korean Patent Application No. 10-2025-0048425, filed in the Korean Intellectual Property Office (KIPO) on Apr. 14, 2025, the disclosure of which is herein incorporated by reference in its entirety.

### BACKGROUND

### FIELD

Some embodiments of the present disclosure relate to a display device and an electronic device including the display device.

### DESCRIPTION OF RELATED ART

There is a growing demand for a display device that allows users to control a viewing angle of an image as needed. The display device that allows for a viewing angle control refers to a display device capable of displaying an image at a wide viewing angle when the user operates the display device in a normal mode and capable of displaying an image at a narrow viewing angle when the user operates the display device in a viewing angle adjustment mode.

Information disclosed in this Background section has already been known to or derived by the inventors before or during the process of achieving the embodiments of the present application, or is technical information acquired in the process of achieving the embodiments. Therefore, it may contain information that does not form prior art that is already known to the public.

### SUMMARY

According to some embodiments of the present disclosure, a display device may be provided.

According to some embodiments of the present disclosure, an electronic device including the display device may be provided.

According to some embodiments of the present disclosure, a display device may include: a first light-emitting layer on a substrate; a second light-emitting layer on the substrate, and spaced apart from the first light-emitting layer in a first direction; a first lens overlapping with the first light-emitting layer, on the first light-emitting layer, the first lens including a first radius of curvature; and a second lens overlapping with the second light-emitting layer, on the second light-emitting layer, the second lens including a second radius of curvature that is smaller than the first radius of curvature.

According to some embodiments of the present disclosure, a light-gathering efficiency of the second lens is greater than a light-gathering efficiency of the first lens.

According to some embodiments of the present disclosure, the display device further includes: a third light-emitting layer on the substrate, and spaced apart from the second light-emitting layer in the first direction; and a third lens overlapping with the third light-emitting layer, on the third light-emitting layer, the third lens comprising a third radius of curvature that is smaller than the second radius of curvature.

According to some embodiments of the present disclosure, the display device further includes: a first light-blocking member adjacent to the first lens, the first light-blocking member comprising a first width in the first direction; and a second light-blocking member adjacent to the second lens, the second light-blocking member comprising a second width in the first direction that is larger than the first width.

According to some embodiments of the present disclosure, the display device further includes: a first lower light-blocking member overlapping with the first light-blocking member, underneath the first light-blocking member, the first lower light-blocking member comprising the first width; and a second lower light-blocking member overlapping with the second light-blocking member, underneath the second light-blocking member, the second lower light-blocking member comprising the second width.

According to some embodiments of the present disclosure, the first light-emitting layer is configured to emit a first light through the first lens, the first light comprising a first front light and a first side light, wherein the second light-emitting layer is configured to emit a second light through the second lens, the second light comprising a second front light and a second side light, wherein each of the first front light and the second front light is emitted in a direction perpendicular to the substrate, wherein the first side light is emitted in a direction at an acute angle with respect to the direction perpendicular to the substrate, wherein the second side light is emitted in the direction at the acute angle with respect to the direction perpendicular to the substrate, and wherein a ratio of a luminance of the second side light to a luminance of the second front light is smaller than a ratio of a luminance of the first side light to a luminance of the first front light.

According to some embodiments of the present disclosure, the display device further includes: a third light-emitting layer on the substrate, and spaced apart from the second light-emitting layer in the first direction; and a third lens overlapping with the third light-emitting layer, on the third light-emitting layer, the third lens comprising a third radius of curvature that is smaller than the second radius of curvature, wherein the third light-emitting layer is configured to emit a third light through the third lens, the third light comprising a third front light and a third side light, and wherein a ratio of a luminance of the third side light to a luminance of the third front light is smaller than the ratio of the luminance of the second side light to the luminance of the second front light.

According to some embodiments of the present disclosure, the display device further includes: a third light-emitting layer on the substrate and adjacent to the first light-emitting layer; and a fourth light-emitting layer on the substrate and adjacent to the second light-emitting layer, wherein no lens is on the third light-emitting layer, and wherein no lens is on the fourth light-emitting layer.

According to some embodiments of the present disclosure, a display device may include: a first light-emitting layer on a substrate; a second light-emitting layer on the substrate, and spaced apart from the first light-emitting layer in a first direction; a first light-blocking member on the first light-emitting layer; a second light-blocking member on the second light-emitting layer; and a second upper light-blocking member overlapping with the second light-blocking member, on the second light-blocking member, wherein a number of light-blocking members vertically stacked on the first light-emitting layer is different from a number of light-blocking members vertically stacked on the second light-emitting layer.

According to some embodiments of the present disclosure, no light-blocking member is on the first light-blocking member.

According to some embodiments of the present disclosure, no light-blocking member is on the second upper light-blocking member.

According to some embodiments of the present disclosure, the display device further includes: a third light-emitting layer on the substrate, and spaced apart from the second light-emitting layer in the first direction; a third light-blocking member on the third light-emitting layer; a third-first upper light-blocking member on the third light-blocking member; and a third-second upper light-blocking member on the third-first upper light-blocking member, wherein a number of light-blocking members vertically stacked on the third light-emitting layer is different from the number of light-blocking members vertically stacked on the first light-emitting layer and the number of light-blocking members vertically stacked on the second light-emitting layer.

According to some embodiments of the present disclosure, no light-blocking member is on the third-second upper light-blocking member.

According to some embodiments of the present disclosure, a width of the first light-blocking member, a width of the second light-blocking member, and a width of the second upper light-blocking member are equal to each other.

According to some embodiments of the present disclosure, a width of the first light-blocking member is smaller than a width of the second light-blocking member.

According to some embodiments of the present disclosure, a width of the second upper light-blocking member is equal to the width of the second light-blocking member.

According to some embodiments of the present disclosure, a display device may include: a first light-emitting layer on a substrate; a second light-emitting layer on the substrate, and spaced apart from the first light-emitting layer in a first direction; a first light-blocking member on the first light-emitting layer and comprising a first width; a second-first light-blocking member on the second light-emitting layer and comprising a second-first width; and a second-second light-blocking member on the second light-emitting layer and between the first light-blocking member and the second-first light-blocking member, the second-second light-blocking member comprising a second-second width that is smaller than the second-first width.

According to some embodiments of the present disclosure, the second-first width is larger than the first width.

According to some embodiments of the present disclosure, the display device further includes: a third light-emitting layer on the substrate, and spaced apart from the first light-emitting layer in a second direction opposite to the first direction; a third-first light-blocking member on the third light-emitting layer and comprising a third-first width; and a third-second light-blocking member on the third light-emitting layer and between the first light-blocking member and the third-first light-blocking member, the third-second light-blocking member comprising a third-second width that is smaller than the third-first width.

According to some embodiments of the present disclosure, an electronic device may include: the display device; and a power module configured to supply power to the display device.

Therefore, a display device according to embodiments may be driven in a viewing angle adjustment mode and may include viewing angle adjustment pixels that emit a light in a viewing angle adjustment mode. The viewing angle adjustment pixels may be arranged in a row within a display panel and may have different luminance characteristics. In an embodiment, a luminance ratio (i.e., a ratio of the luminance of the side light to the luminance of the front light) of a viewing angle adjustment pixel located at a peripheral region (or referred to as an outer region) of the display panel may be smaller than a luminance ratio of a viewing angle adjustment pixel located at a central region (or referred to as a center region) of the display panel.

For example, the luminance ratios of the viewing angle adjustment pixels may decrease in a direction from the central region to the peripheral region of the display panel. Accordingly, while the display device is driven in the viewing angle adjustment mode, a light intensity measured at a front of the display device may be greater than a light intensity measured at a front of a conventional display device. That is, while the display device is driven in the viewing angle adjustment mode, a luminance profile according to a viewing angle of the display device may be improved. As a result, an amount of change in luminance according to the viewing angle felt by a user who views an image at the front of the display device may be reduced, and thus dizziness or eye fatigue of the user may be reduced.

However, aspects and effects of embodiments of the present disclosure are not limited to the above aspects and effects, and other aspects and effects of embodiments of the present disclosure may be variously provided without departing from the spirit and scope of the present disclosure.

### BRIEF DESCRIPTION OF DRAWINGS

Non-limiting example embodiments of the present disclosure will be more clearly understood from the following detailed description in conjunction with the accompanying drawings, in which.

FIG. 1 is a block diagram illustrating a display device according to embodiments.

FIG. 2 is a circuit diagram illustrating a normal pixel included in the display device of FIG. 1.

FIG. 3 is a plan view for describing the display device of FIG. 1.

FIG. 4 is a graph for describing luminance ratios of viewing angle adjustment pixels included in the display device of FIG. 3.

FIG. 5 is a diagram illustrating an example in which the display device of FIG. 3 operates in a normal mode.

FIG. 6 is a diagram illustrating an example in which the display device of FIG. 3 operates in a viewing angle adjustment mode.

FIG. 7 is a graph for describing an intensity of a light measured at a front of the display device of FIG. 3 while the display device of FIG. 3 is driven in a normal mode or in a viewing angle adjustment mode.

FIG. 8 is a cross-sectional view for describing a display device according to an embodiment.

FIG. 9A is a cross-sectional view illustrating an example of viewing angle adjustment pixels included in the display device of FIG. 8.

FIG. 9B is a cross-sectional view illustrating another example of viewing angle adjustment pixels included in the display device of FIG. 8.

FIG. 10 is a cross-sectional view illustrating normal pixels included in the display device of FIG. 8.

FIG. 11 is a cross-sectional view illustrating viewing angle adjustment pixels included in a display device according to an embodiment.

FIG. 12 is a cross-sectional view illustrating viewing angle adjustment pixels included in a display device according to an embodiment.

FIG. 13A is a cross-sectional view illustrating an example of viewing angle adjustment pixels included in a display device according to an embodiment.

FIG. 13B is a cross-sectional view illustrating another example of viewing angle adjustment pixels included in a display device according to an embodiment.

FIG. 14 is a cross-sectional view illustrating viewing angle adjustment pixels included in a display device according to an embodiment.

FIG. 15 is a cross-sectional view illustrating viewing angle adjustment pixels included in a display device according to an embodiment.

FIG. 16 is a cross-sectional view illustrating viewing angle adjustment pixels included in a display device according to an embodiment.

FIG. 17 is a graph for describing an intensity of a light measured at a front of a display device according to an embodiment while the display device is driven in a normal mode or in a viewing angle adjustment mode.

FIG. 18 is a block diagram illustrating an electronic device according to embodiments.

FIG. 19 is a schematic diagram illustrating the electronic device of FIG. 18.

### DETAILED DESCRIPTION

Hereinafter, non-limiting example embodiments of the present disclosure will be described in more detail with reference to the attached drawings. Identical components in the drawings will be designated by the same reference numerals, and redundant descriptions of the identical components will be omitted.

It will be understood that when an element or layer is referred to as being “on,” “connected to,” or “coupled to” another element or layer, it can be directly on, connected to, or coupled to the other element or layer or intervening elements or layers may be present. In contrast, when an element or layer is referred to as being “directly on,” “directly connected to,” or “directly coupled to” another element or layer, there are no intervening elements or layers present.

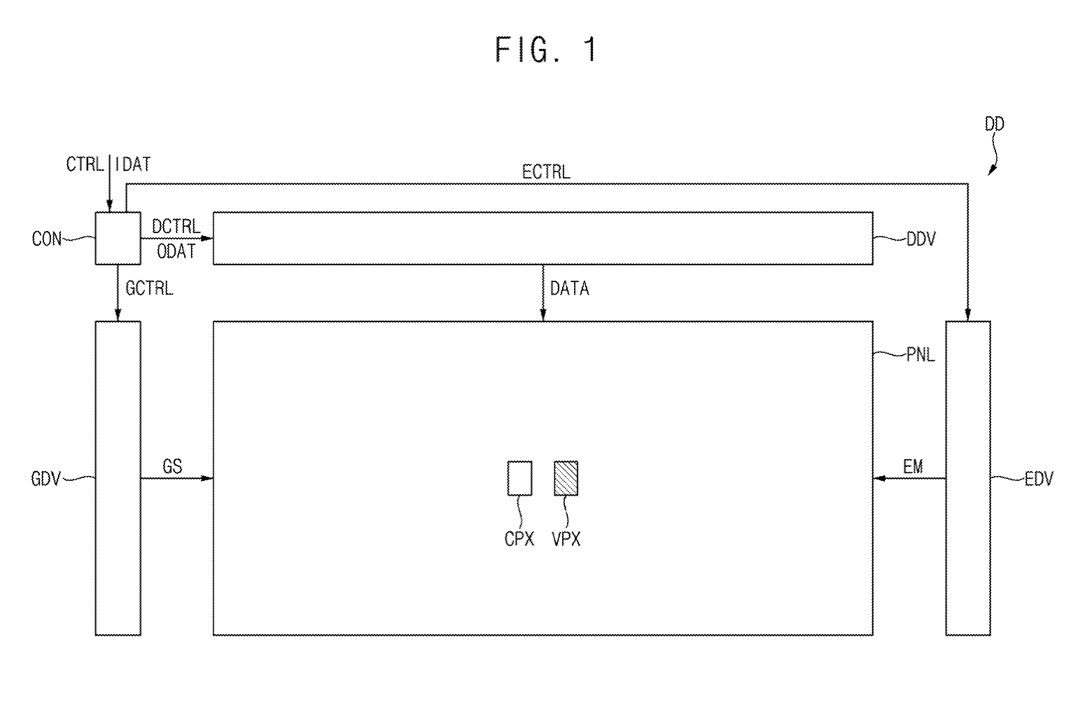

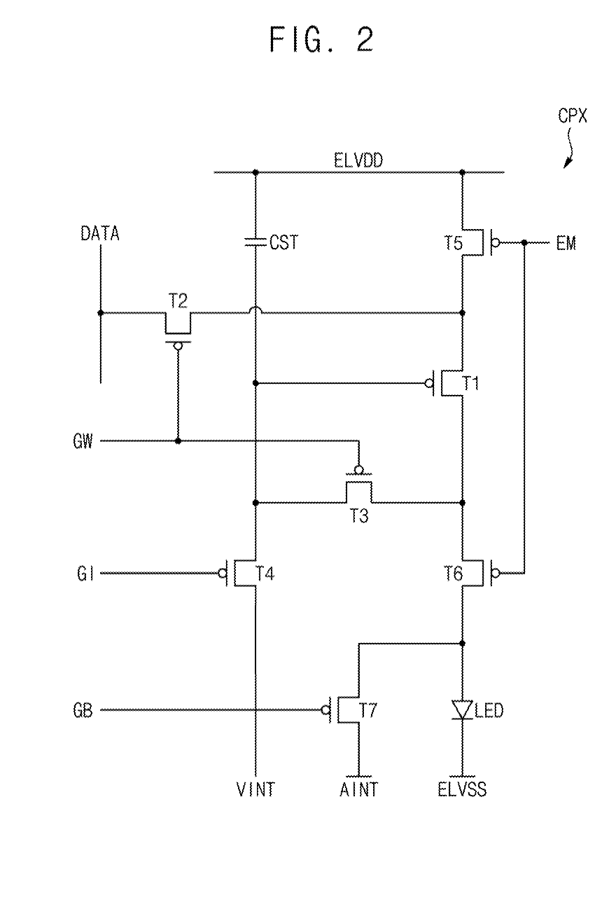

FIG. 1 is a block diagram illustrating a display device according to embodiments, and FIG. 2 is a circuit diagram illustrating a normal pixel included in the display device of FIG. 1.

Referring to FIG. 1, the display device DD may include a display panel PNL, a data driver DDV (also referred to as a data driving unit, a data driving circuit, and the like), a gate driver GDV (also referred to as a gate driving unit, a gate driving circuit, and the like) , a light-emitting driver EDV (also referred to as a light-emitting driving unit, a light-emitting driving circuit, and the like), and a controller CON (also referred to as a control unit, a control circuit, and the like).

The display panel PNL may include at least one normal pixel CPX and at least one viewing angle adjustment pixel VPX. The display panel PNL may display an image using the normal pixel CPX and the viewing angle adjustment pixel VPX.

In an embodiment, the normal pixel CPX may be a pixel whose viewing angle is not adjusted, and the viewing angle adjustment pixel VPX may be a pixel whose viewing angle is adjusted. For example, a lens and/or a light-blocking member may be formed in the viewing angle adjustment pixel VPX. Accordingly, a light having an angle greater than a predetermined viewing angle may not be emitted from the viewing angle adjustment pixel VPX.

In an embodiment, the display device DD may be driven in a first mode (e.g., a normal mode) and in a second mode (e.g., a viewing angle adjustment mode). In the first mode, the normal pixel CPX and the viewing angle adjustment pixel VPX may emit the light. In the second mode, the normal pixel CPX may not emit the light, and the viewing angle adjustment pixel VPX may emit the light.

The data driver DDV may be electrically connected to the at least one normal pixel CPX and the at least one viewing angle adjustment pixel VPX. The data driver DDV may generate a data voltage DATA based on output image data ODAT and may transmit the data voltage DATA based on a data control signal DCTRL. For example, the output image data ODAT may be red, green, blue (RGB) data for an image displayed on the display panel PNL, and the data control signal DCTRL may include an output data enable signal, a horizontal start signal, a load signal, etc.

The gate driver GDV may be electrically connected to the at least one normal pixel CPX and the at least one viewing angle adjustment pixel VPX. The gate driver GDV may generate a gate signal GS based on a gate control signal GCTRL. In addition, the gate driver GDV may sequentially output the gate signal GS. For example, the gate control signal GCTRL may include a vertical start signal, a clock signal, etc.

The light-emitting driver EDV may be electrically connected to the at least one normal pixel CPX and the at least one viewing angle adjustment pixel VPX. The light-emitting driver EDV may generate a light-emitting driving signal EM based on a light-emitting control signal ECTRL. In addition, the light-emitting driver EDV may sequentially output the light-emitting driving signal EM. For example, the light-emitting control signal ECTRL may include a vertical start signal, a clock signal, etc.

The controller CON (e.g., a timing controller) may receive input image data IDAT and a control signal CTRL from an external host processor (e.g., graphics processing unit (GPU)). For example, the input image data DAT may be the RGB data including red color image data, green color image data, and blue color image data. The control signal CTRL may include a vertical synchronization signal, a horizontal synchronization signal, an input data enable signal, a master clock signal, etc. The controller CON may generate the output image data ODAT, the data control signal DCTRL, the gate control signal GCTRL, and the light-emitting control signal ECTRL based on the input image data IDAT and the control signal CTRL.

Referring to FIG. 2, the normal pixel CPX may include a first transistor T1, a second transistor T2, a third transistor T3, a fourth transistor T4, a fifth transistor T5, a sixth transistor T6, a seventh transistor T7, a storage capacitor CST, and a light-emitting element LED.

The first transistor T1 may include a gate terminal, a first terminal, and a second terminal. The gate terminal of the first transistor T1 may be electrically connected to the storage capacitor CST. The first terminal of the first transistor T1 may receive a high power supply voltage ELVDD through the fifth transistor T5. The second terminal of the first transistor T1 may be electrically connected to the light-emitting element LED through the sixth transistor T6.

The first transistor T1 may generate a driving current based on a voltage difference between the gate terminal of the first transistor T1 and the first terminal of the first transistor T1.

The second transistor T2 may include a gate terminal, a first terminal, and a second terminal. The gate terminal of the second transistor T2 may receive a first gate signal GW. The first terminal of the second transistor T2 may receive the data voltage DATA. The second terminal of the second transistor T2 may be electrically connected to the first terminal of the first transistor T1.

The second transistor T2 may be turned on or off in response to the first gate signal GW. For example, when the second transistor T2 is a p-channel metal-oxide semiconductor (PMOS) transistor, the second transistor T2 may be turned off when the first gate signal GW has a positive voltage level and may be turned on when the first gate signal GW has a negative voltage level. During a period in which the second transistor T2 is turned on, the second transistor T2 may transmit the data voltage DATA.

The third transistor T3 may include a gate terminal, a first terminal, and a second terminal. The gate terminal of the third transistor T3 may receive the first gate signal GW. The first terminal of the third transistor T3 may be electrically connected to the second terminal of the first transistor T1. The second terminal of the third transistor T3 may be electrically connected to the gate terminal of the first transistor T1.

The third transistor T3 may be turned on or off in response to the first gate signal GW. For example, when the third transistor T3 is a PMOS transistor, the third transistor T3 may be turned off when the first gate signal GW has a positive voltage level and may be turned on when the first gate signal GW has a negative voltage level. During a period in which the third transistor T3 is turned on, the third transistor T3 may diode-connect the first transistor T1. Accordingly, the third transistor T3 may compensate for a threshold voltage of the first transistor T1.

The fourth transistor T4 may include a gate terminal, a first terminal, and a second terminal. The gate terminal of the fourth transistor T4 may receive a second gate signal GI. The first terminal of the fourth transistor T4 may receive an initialization voltage VINT. The second terminal of the fourth transistor T4 may be electrically connected to the gate terminal of the first transistor T1.

The fourth transistor T4 may be turned on or off in response to the second gate signal GI. For example, when the fourth transistor T4 is a PMOS transistor, the fourth transistor T4 may be turned off when the second gate signal GI has a positive voltage level and may be turned on when the second gate signal GI has a negative voltage level. During a period in which the fourth transistor T4 is turned on, the fourth transistor T4 may transmit the initialization voltage VINT. Accordingly, the fourth transistor T4 may initialize the gate terminal of the first transistor T1.

The fifth transistor T5 may include a gate terminal, a first terminal, and a second terminal. The gate terminal of the fifth transistor T5 may receive the light-emitting driving signal EM. The first terminal of the fifth transistor T5 may receive the high power supply voltage ELVDD. The second terminal of the fifth transistor T5 may be electrically connected to the first transistor T1.

The fifth transistor T5 may be turned on or off in response to the light-emitting driving signal EM. For example, when the fifth transistor T5 is a PMOS transistor, the fifth transistor T5 may be turned off when the light-emitting driving signal EM has a positive voltage level and may be turned on when the light-emitting driving signal EM has a negative voltage level. During a period in which the fifth transistor T5 is turned on, the fifth transistor T5 may transmit the high power supply voltage ELVDD.

The sixth transistor T6 may include a gate terminal, a first terminal, and a second terminal. The gate terminal of the sixth transistor T6 may receive the light-emitting driving signal EM. The first terminal of the sixth transistor T6 may be electrically connected to the first transistor T1. The second terminal of the sixth transistor T6 may be electrically connected to the light-emitting element LED.

The sixth transistor T6 may be turned on or off in response to the light-emitting driving signal EM. For example, when the sixth transistor T6 is a PMOS transistor, the sixth transistor T6 may be turned off when the light-emitting driving signal EM has a positive voltage level and may be turned on when the light-emitting driving signal EM has a negative voltage level. During a period in which the sixth transistor T6 is turned on, the sixth transistor T6 may transmit the driving current.

The seventh transistor T7 may include a gate terminal, a first terminal, and a second terminal. The gate terminal of the seventh transistor T7 may receive a third gate signal GB. The first terminal of the seventh transistor T7 may receive an anode initialization voltage AINT. The second terminal of the seventh transistor T7 may be electrically connected to the light-emitting element LED.

The seventh transistor T7 may be turned on or off in response to the third gate signal GB. For example, when the seventh transistor T7 is a PMOS transistor, the seventh transistor T7 may be turned off when the third gate signal GB has a positive voltage level and may be turned on when the third gate signal GB has a negative voltage level. During a period in which the seventh transistor T7 is turned on, the seventh transistor T7 may transmit the anode initialization voltage AINT.

The storage capacitor CST may include a first terminal and a second terminal. The first terminal of the storage capacitor CST may receive the high power supply voltage ELVDD. The second terminal of the storage capacitor CST may be electrically connected to the gate terminal of the first transistor T1.

The light-emitting element LED may include a first terminal and a second terminal. The first terminal of the light-emitting element LED may be electrically connected to the first transistor T1 via the sixth transistor T6. The second terminal of the light-emitting element LED may receive a low power supply voltage ELVSS. The light-emitting element LED may emit the light based on the driving current.

The first to seventh transistors T1, T2, T3, T4, T5, T6, and T7 may be implemented as PMOS transistors, respectively, but embodiments of the present disclosure are not limited thereto. For example, at least one of the first to seventh transistors T1, T2, T3, T4, T5, T6, and T7 may be implemented as an n-channel metal-oxide semiconductor (NMOS) transistor.

In addition, according to various embodiments of the present disclosure, the number of transistors, the number of capacitors, a connection relationship between the transistors and the capacitors and the like described above may be appropriately changed.

In an embodiment, the viewing angle adjustment pixel VPX may have substantially the same circuit structure as the circuit structure of the normal pixel CPX. In another embodiment, the viewing angle adjustment pixel VPX may have a different circuit structure from the circuit structure of the normal pixel CPX.

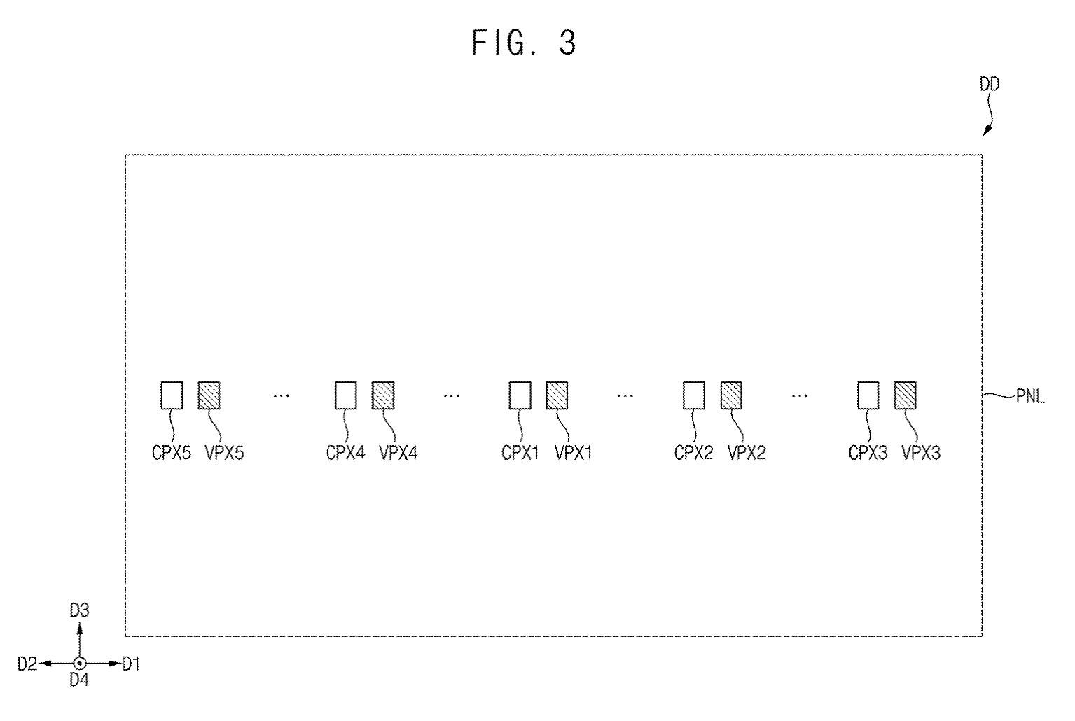

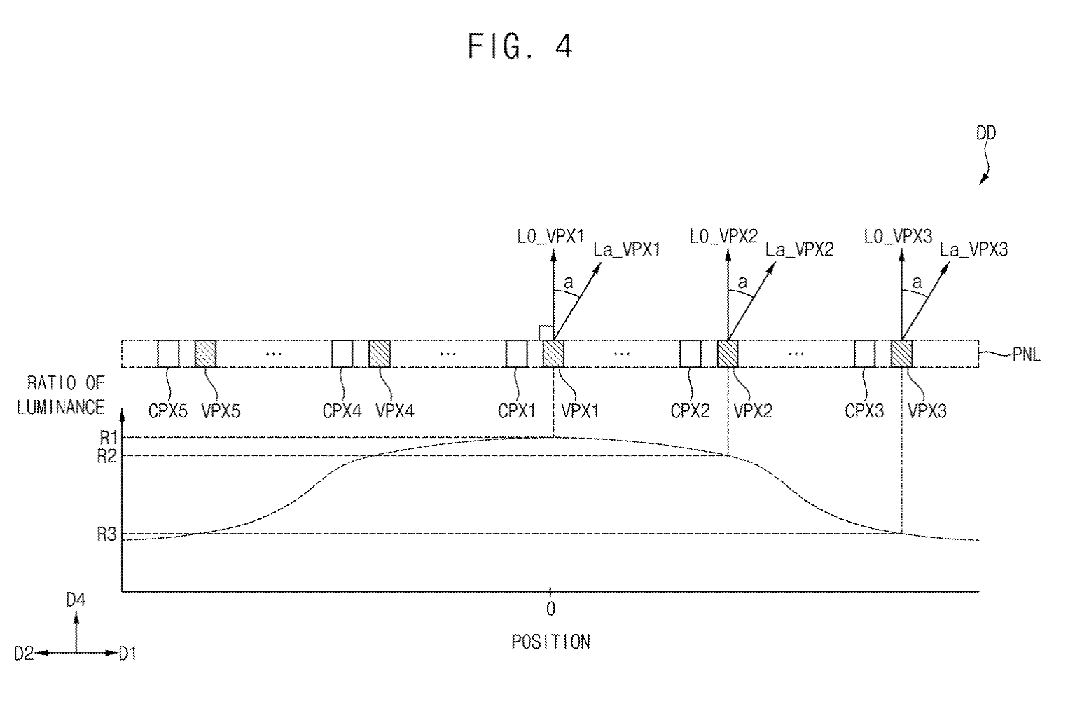

FIG. 3 is a plan view for describing the display device of FIG. 1, and FIG. 4 is a graph for describing luminance ratios of viewing angle adjustment pixels included in the display device of FIG. 3.

Referring to FIG. 3, the display device DD may include the display panel PNL, and the display panel PNL may have a display surface formed in a first direction D1, a second direction D2 opposite to the first direction D1, and a third direction D3 perpendicular to the first direction D1 and the second direction D2. In addition, the display panel PNL may have a thickness in a fourth direction D4 perpendicular to the first direction D1, the second direction D2, and the third direction D3.

On the display surface of the display panel PNL, a plurality of normal pixels and a plurality of viewing angle adjustment pixels may be arranged.

For example, the normal pixels CPX may include a first normal pixel CPX1, a second normal pixel CPX2, a third normal pixel CPX3, a fourth normal pixel CPX4, and a fifth normal pixel CPX5.

In an embodiment, the first normal pixel CPX1 may be located (or positioned) at a central region of the display panel PNL. The second normal pixel CPX2 may be spaced apart from the first normal pixel CPX1 in the first direction D1, and the third normal pixel CPX3 may be spaced apart from the second normal pixel CPX2 in the first direction D1. The fourth normal pixel CPX4 may be spaced apart from the first normal pixel CPX1 in the second direction D2, and the fifth normal pixel CPX5 may be spaced apart from the fourth normal pixel CPX4 in the second direction D2.

The third normal pixel CPX3 may be located at a peripheral region of the display panel PNL, and the second normal pixel CPX2 may be located between the first normal pixel CPX1 and the third normal pixel CPX3. The fifth normal pixel CPX5 may be located at the peripheral region of the display panel PNL, and the fourth normal pixel CPX4 may be located between the first normal pixel CPX1 and the fifth normal pixel CPX5.

For example, the viewing angle adjustment pixels VPX may include a first viewing angle adjustment pixel VPX1, a second viewing angle adjustment pixel VPX2, a third viewing angle adjustment pixel VPX3, a fourth viewing angle adjustment pixel VPX4, and a fifth viewing angle adjustment pixel VPX5.

In an embodiment, the first viewing angle adjustment pixel VPX1 may be located (or positioned) at the central region of the display panel PNL. The second viewing angle adjustment pixel VPX2 may be spaced apart from the first viewing angle adjustment pixel VPX1 in the first direction D1, and the third viewing angle adjustment pixel VPX3 may be spaced apart from the second viewing angle adjustment pixel VPX2 in the first direction D1. The fourth viewing angle adjustment pixel VPX4 may be spaced apart from the first viewing angle adjustment pixel VPX1 in the second direction D2, and the fifth viewing angle adjustment pixel VPX5 may be spaced apart from the fourth viewing angle adjustment pixel VPX4 in the second direction D2.

The third viewing angle adjustment pixel VPX3 may be located at the peripheral region of the display panel PNL, and the second viewing angle adjustment pixel VPX2 may be located between the first viewing angle adjustment pixel VPX1 and the third viewing angle adjustment pixel VPX3. The fifth viewing angle adjustment pixel VPX5 may be located at the peripheral region of the display panel PNL, and the fourth viewing angle adjustment pixel VPX4 may be located between the first viewing angle adjustment pixel VPX1 and the fifth viewing angle adjustment pixel VPX5.

In an embodiment, the first normal pixel CPX1 may be adjacent to the first viewing angle adjustment pixel VPX1, the second normal pixel CPX2 may be adjacent to the second viewing angle adjustment pixel VPX2, the third normal pixel CPX3 may be adjacent to the third viewing angle adjustment pixel VPX3, the fourth normal pixel CPX4 may be adjacent to the fourth viewing angle adjustment pixel VPX4, and the fifth normal pixel CPX5 may be adjacent to the fifth viewing angle adjustment pixel VPX5.

Referring to FIG. 4, in an embodiment, the light emitted from the viewing angle adjustment pixels VPX may include a front light and a side light. The front light may be a light emitted in a direction perpendicular to the display panel PNL (e.g., the fourth direction D4). The side light may be a light emitted in a direction at an acute angle (e.g., indicated by an angle a) with respect to the direction perpendicular to the display panel PNL. The acute angle (e.g., indicated by an angle an angle a) may be a predetermined angle between 0 and 90 degrees and may be, for example, approximately 35 degrees.

In an embodiment, a luminance ratio may be defined for each of the viewing angle adjustment pixels VPX. The luminance ratio may be defined as a ratio of the luminance of the side light to the luminance of the front light.

In an embodiment, the light emitted from the first viewing angle adjustment pixel VPX1 may include a first front light L0_VPX1 and a first side light La_VPX1. The first front light L0_VPX1 may be a light emitted in a vertical direction (e.g., the fourth direction D4) with respect to the display panel PNL (e.g., the vertical direction may be the direction perpendicular to the display panel PNL). The first side light La_VPX1 may be a light emitted in a direction at an acute angle (e.g., indicated by an angle a) with respect to the vertical direction.

In an embodiment, a first luminance ratio R1 of the first viewing angle adjustment pixel VPX1 may be defined as a ratio of the luminance of the first side light La_VPX1 to the luminance of the first front light L0_VPX1. That is, the first luminance ratio R1 of the first viewing angle adjustment pixel VPX1 may be calculated by R1=La_VPX1/L0_VPX1.

In an embodiment, the light emitted from the second viewing angle adjustment pixel VPX2 may include a second front light L0_VPX2 and a second side light La_VPX2. The second front light L0_VPX2 may be a light emitted in a vertical direction (e.g., the fourth direction D4) with respect to the display panel PNL (e.g., the vertical direction may be the direction perpendicular to the display panel PNL). The second side light La_VPX2 may be a light emitted in a direction at an acute angle (e.g., indicated by an angle a) with respect to the vertical direction.

In an embodiment, a second luminance ratio R2 of the second viewing angle adjustment pixel VPX2 may be defined as a ratio of the luminance of the second side light La_VPX2 to the luminance of the second front light L0_VPX2. That is, the second luminance ratio R2 of the second viewing angle adjustment pixel VPX2 may be calculated by R2=La_VPX2/L0_VPX2.

In an embodiment, the light emitted from the third viewing angle adjustment pixel VPX3 may include a third front light L0_VPX3 and a third side light La_VPX3. The third front light L0_VPX3 may be a light emitted in a vertical direction (e.g., the fourth direction D4) with respect to the display panel PNL (e.g., the vertical direction may be the direction perpendicular to the display panel PNL). The third side light La_VPX3 may be a light emitted in a direction at an acute angle (e.g., indicated by an angle a) with respect to the vertical direction.

In an embodiment, a third luminance ratio R3 of the third viewing angle adjustment pixel VPX3 may be defined as a ratio of the luminance of the third side light La_VPX3 to the luminance of the third front light L0_VPX3. That is, the third luminance ratio R3 of the third viewing angle adjustment pixel VPX3 may be calculated by R3=La_VPX3/L0_VPX3.

In an embodiment, the luminance ratios defined for each of the viewing angle adjustment pixels VPX may be different from each other. For example, the luminance ratio of the viewing angle adjustment pixel VPX located at the peripheral region of the display panel PNL may be smaller than the luminance ratio of the viewing angle adjustment pixel VPX located at the central region of the display panel PNL. In other words, as illustrated in FIG. 4, the luminance ratio may decrease toward the peripheral region of the display panel PNL.

In an embodiment, the third luminance ratio R3 may be smaller than the second luminance ratio R2, and the second luminance ratio R2 may be smaller than the first luminance ratio R1. For example, the luminance of the third side light La_VPX3 may be smaller than the luminance of the second side light La_VPX2, and the luminance of the second side light La_VPX2 may be smaller than the luminance of the first side light La_VPX1.

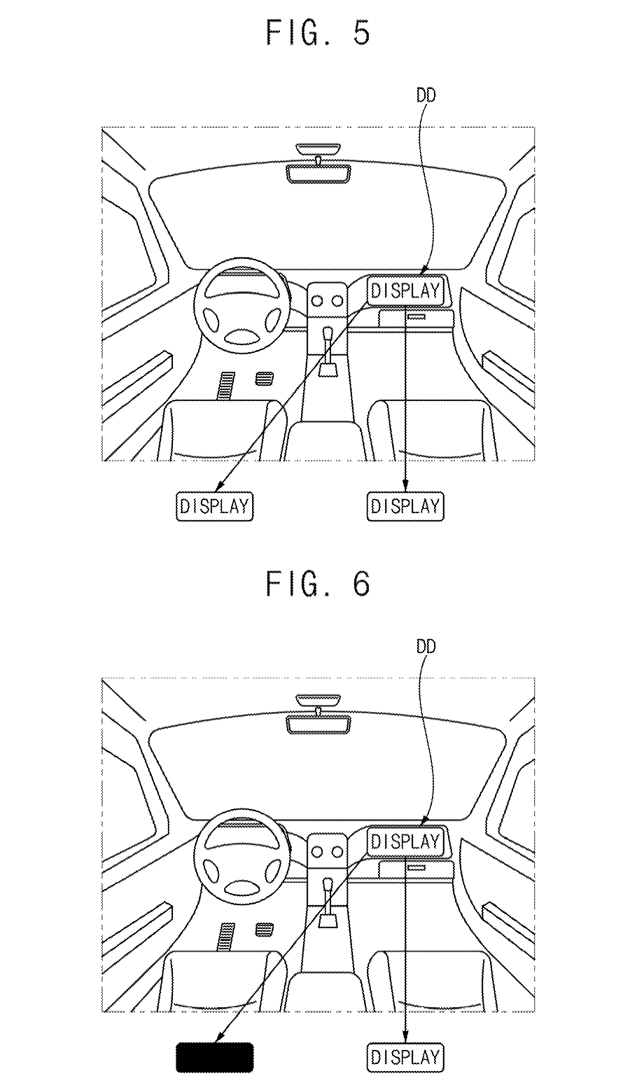

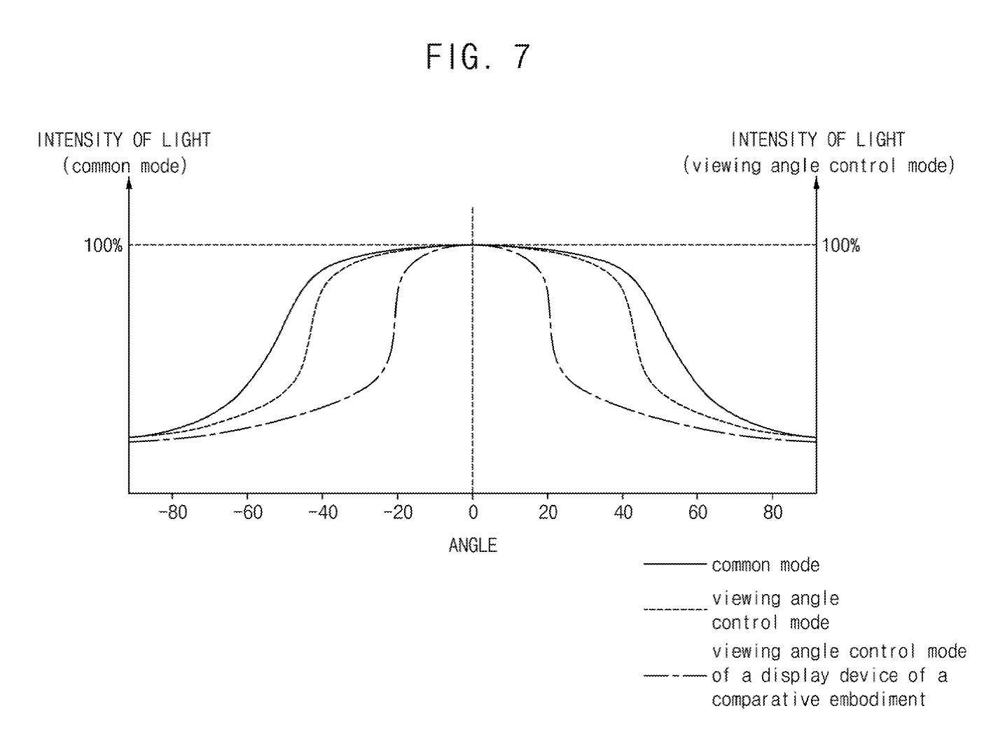

FIG. 5 is a diagram illustrating an example in which the display device of FIG. 3 operates in a normal mode, FIG. 6 is a diagram illustrating an example in which the display device of FIG. 3 operates in a viewing angle adjustment mode, and FIG. 7 is a graph for describing an intensity of light measured at a front of the display device of FIG. 3 while the display device of FIG. 3 is driven in a normal mode or in a viewing angle adjustment mode.

Referring to FIG. 5, for example, the display device DD may be installed in a vehicle. While the vehicle is stopped, the display device DD may operate in a normal mode. In this case, a driver and a passenger in a front seat may be permitted to view an image.

Referring to FIG. 6, while the vehicle is driving, the display device DD may operate in a viewing angle adjustment mode. In this case, the driver may be restricted from viewing the image, but the passenger in the front seat may be permitted to view the image.

Referring to FIG. 7, as described above, in the display device DD, the luminance ratios of the viewing angle adjustment pixels VPX may decrease in the direction from the central region to the peripheral region of the display panel PNL. On the other hand, in a display device of a comparative embodiment, the luminance ratios of the viewing angle adjustment pixels arranged on the display panel may be the same as each other.

While the display device DD is driven in the viewing angle adjustment mode, the intensity of the light measured at the front of the display device DD may be greater than the intensity of the light measured at the front of the display device of the comparative embodiment. In other words, while the display device DD is driven in the viewing angle adjustment mode, a profile of the luminance according to the viewing angle of the display device DD may be improved. Accordingly, an amount of change in the luminance according to the viewing angle felt by a user (e.g., the passenger) who views the image at the front of the display device DD may be reduced, and thus dizziness or eye fatigue of the user may be reduced.

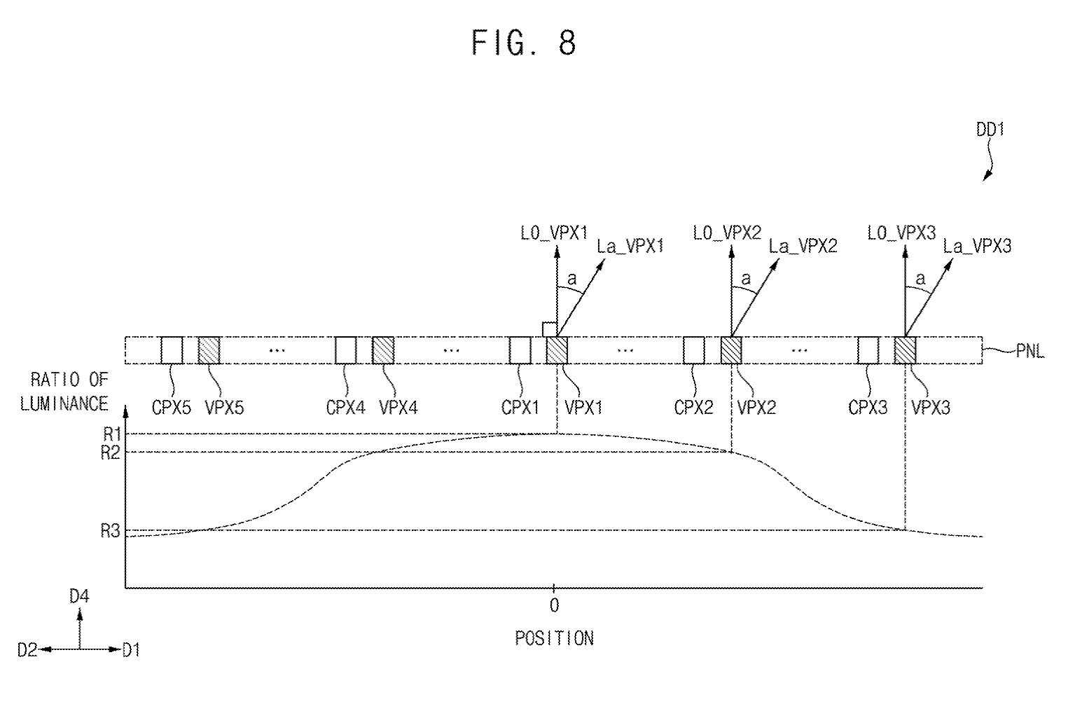

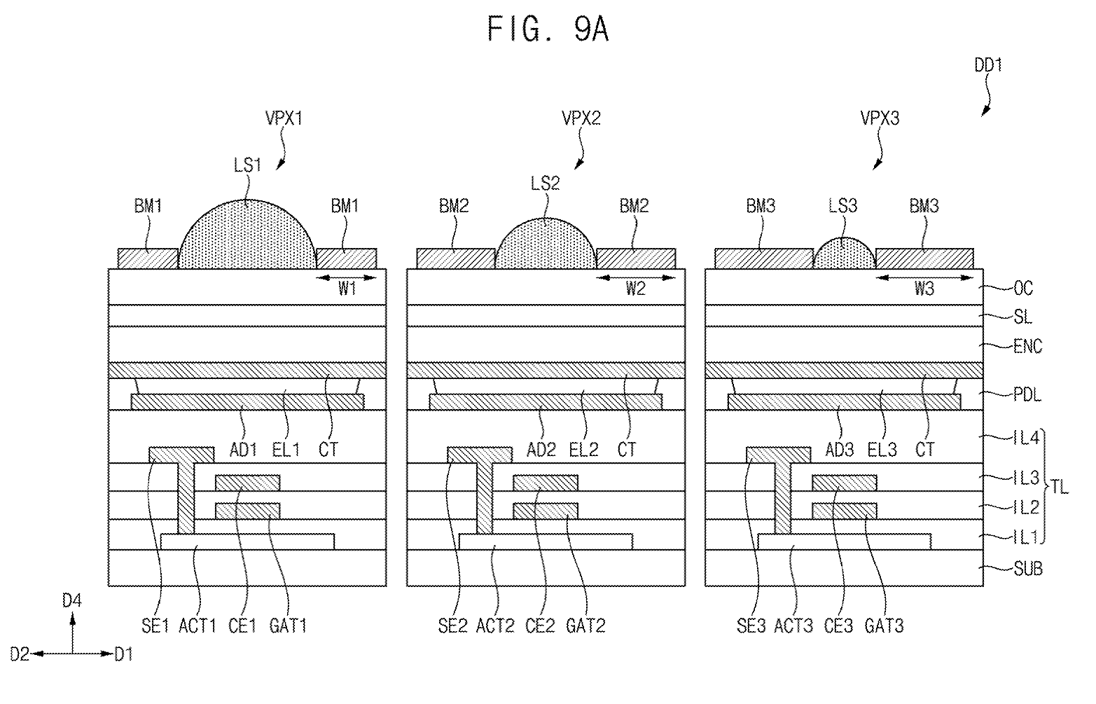

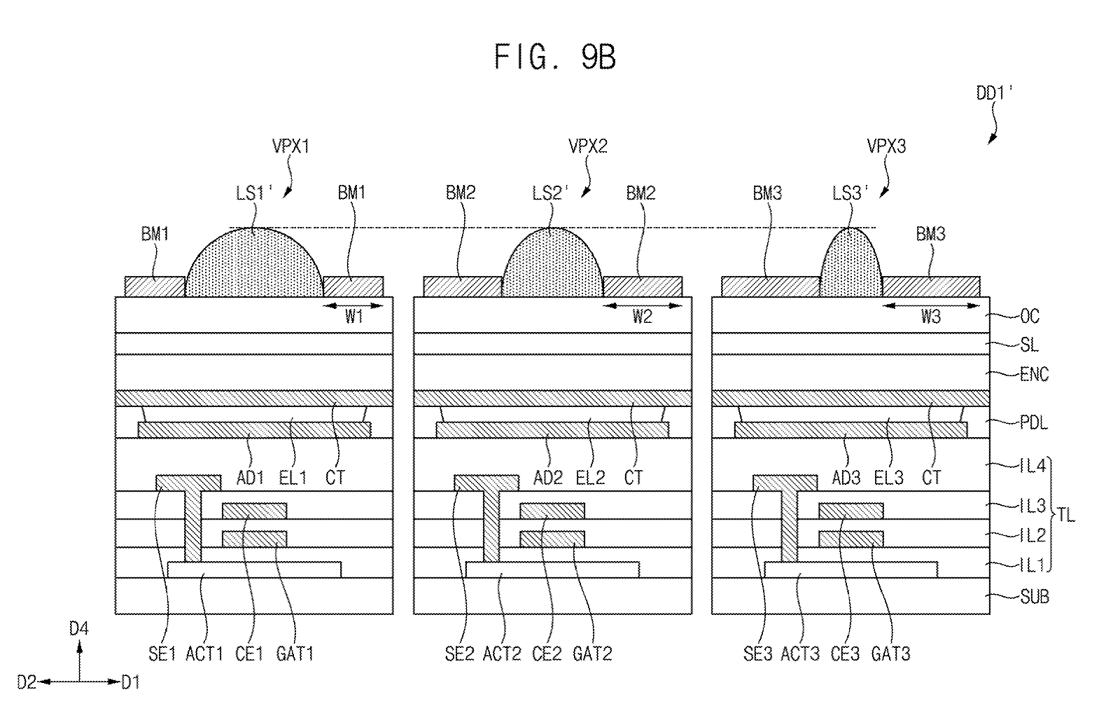

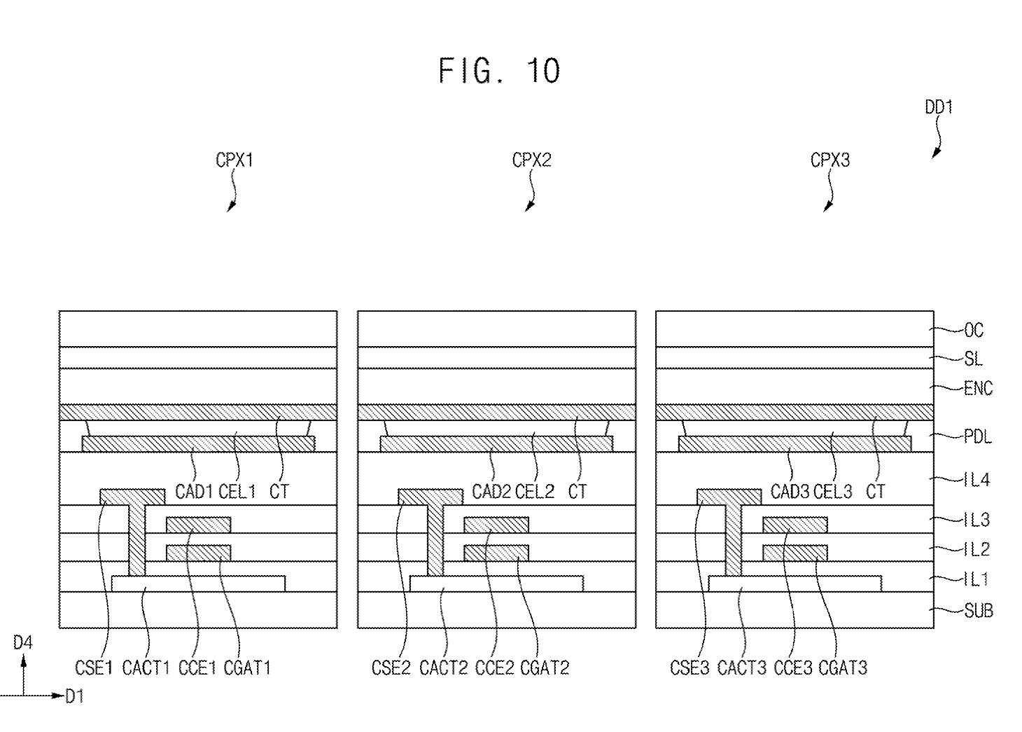

FIG. 8 is a cross-sectional view for describing a display device according to one embodiment, FIG. 9A is a cross-sectional view illustrating an example of viewing angle adjustment pixels included in the display device of FIG. 8, FIG. 9B is a cross-sectional view illustrating another example of viewing angle adjustment pixels included in the display device of FIG. 8, and FIG. 10 is a cross-sectional view illustrating normal pixels included in the display device of FIG. 8.

Referring to FIG. 8, the display device DD1 may include the normal pixels CPX and the viewing angle adjustment pixels VPX described above with reference to FIG. 4. In addition, as described above, the luminance ratios of the viewing angle adjustment pixels VPX may decrease in the direction from the central region to the peripheral region of the display panel PNL.

Referring to FIG. 9A, the display device DD1 may include a substrate SUB, a transistor layer TL, a first pixel electrode AD1, a second pixel electrode AD2, a third pixel electrode AD3, a pixel defining layer PDL, a first light-emitting layer EL1, a second light-emitting layer EL2, a third light-emitting layer EL3, a common electrode CT, an encapsulation layer ENC, a sensing layer SL, a planarization layer OC, a first lens LS1, a second lens LS2, a third lens LS3, a first light-blocking member BM1, a second light-blocking member BM2, and a third light-blocking member BM3.

The transistor layer TL may include a first active pattern ACT1, a second active pattern ACT2, a third active pattern ACT3, a first insulating layer IL1, a first gate electrode GAT1, a second gate electrode GAT2, a third gate electrode GAT3, a second insulating layer IL2, a first capacitor electrode CE1, a second capacitor electrode CE2, a third capacitor electrode CE3, a third insulating layer IL3, a first connection electrode SE1, a second connection electrode SE2, a third connection electrode SE3, and a fourth insulating layer IL4.

The substrate SUB may be an insulating substrate formed of a transparent or opaque material. In an embodiment, the substrate SUB may include glass. In this case, the display panel PNL may be a rigid display panel. In another embodiment, the substrate SUB may include plastic. In this case, the display panel PNL may be a flexible display panel.

The first active pattern ACT1 may be disposed on the substrate SUB. In an embodiment, the first active pattern ACT1 may include a silicon semiconductor. For example, the first active pattern ACT1 may include amorphous silicon, polycrystalline silicon, or the like. In another embodiment, the first active pattern ACT1 may include an oxide semiconductor.

The second active pattern ACT2 and the third active pattern ACT3 may be formed together with the first active pattern ACT1, and may have a structure that is the same as or similar to the structure of the first active pattern ACT 1.

The first insulating layer IL1 may cover the first to third active patterns ACT1, ACT2, and ACT3 and may be disposed on the substrate SUB. In an embodiment, the first insulating layer IL1 may include an insulating material. For example, the first insulating layer IL1 may include silicon oxide, silicon nitride, silicon oxynitride, or the like.

The first gate electrode GAT1 may be disposed on the first insulating layer IL1 and may overlap with the first active pattern ACT1. In an embodiment, the first gate electrode GAT1 may include a metal, an alloy, a conductive metal oxide, a transparent conductive material, or the like. For example, the first gate electrode GAT1 may include silver (Ag), an alloy containing silver, molybdenum (Mo), an alloy containing molybdenum, aluminum (Al), an alloy containing aluminum, aluminum nitride (AlN), tungsten (W), tungsten nitride (WN), copper (Cu), nickel (Ni), chromium (Cr), chromium nitride (CrN), titanium (Ti), tantalum (Ta), platinum (Pt), scandium (Sc), indium tin oxide (ITO), indium zinc oxide (IZO), or the like. These materials may be used alone or in combination with each other. Additionally, the first gate electrode GAT1 may be formed to have a single-layer structure or a multi-layer structure.

The second gate electrode GAT2 the third gate electrode GAT3 may be formed together with the first gate electrode GAT1, may overlap with the second active pattern ACT2 and the third active pattern ACT3, respectively, and may include a structure that is the same as or similar to the structure of the first gate electrode GAT1.

The second insulating layer IL2 may cover the first to third gate electrodes GAT1, GAT2, and GAT3 and may be disposed on the first insulating layer IL1. In an embodiment, the second insulating layer IL2 may include an insulating material. For example, the second insulating layer IL2 may include silicon oxide, silicon nitride, silicon oxynitride, or the like.

The first capacitor electrode CE1 may be disposed on the second insulating layer IL2 and may overlap with the first gate electrode GAT1. In an embodiment, the first capacitor electrode CE1 may include a metal, an alloy, a conductive metal oxide, a transparent conductive material, or the like. For example, the first capacitor electrode CE1 may include silver (Ag), an alloy containing silver, molybdenum (Mo), an alloy containing molybdenum, aluminum (Al), an alloy containing aluminum, aluminum nitride (AlN), tungsten (W), tungsten nitride (WN), copper (Cu), nickel (Ni), chromium (Cr), chromium nitride (CrN), titanium (Ti), tantalum (Ta), platinum (Pt), scandium (Sc), indium tin oxide (ITO), indium zinc oxide (IZO), or the like. These materials may be used alone or in combination with each other. Additionally, the first capacitor electrode CE1 may be formed to have a single-layer structure or a multi-layer structure.

The second capacitor electrode CE2 and the third capacitor electrode CE3 may be formed together with the first capacitor electrode CE1, may overlap with the second gate electrode GAT2 and the third gate electrode GAT3, respectively, and may include a structure that is the same as or similar to the structure of the first capacitor electrode CE1.

The third insulating layer IL3 may cover the first to third capacitor electrodes CE1, CE2, and CE3 and may be disposed on the second insulating layer IL2. In an embodiment, the third insulating layer IL3 may include an insulating material. For example, the third insulating layer IL3 may include silicon oxide, silicon nitride, silicon oxynitride, or the like.

The first connection electrode SE1 may be disposed on the third insulating layer IL3 and may be in contact (e.g., direct contact) with the first active pattern ACT1. For example, a portion of the first connection electrode SE1 may penetrate the third insulating layer IL3, the second insulating layer IL2, and the first insulating layer IL1 to contact (e.g., directly contact) the first active pattern ACT1. In an embodiment, the first connection electrode SE1 may include a metal, an alloy, a conductive metal oxide, a transparent conductive material, or the like. For example, the first connection electrode SE1 may include silver (Ag), an alloy containing silver, molybdenum (Mo), an alloy containing molybdenum, aluminum (Al), an alloy containing aluminum, aluminum nitride (AlN), tungsten (W), tungsten nitride (WN), copper (Cu), nickel (Ni), chromium (Cr), chromium nitride (CrN), titanium (Ti), tantalum (Ta), platinum (Pt), scandium (Sc), indium tin oxide (ITO), indium zinc oxide (IZO), or the like. These materials may be used alone or in combination with each other. Additionally, the first connection electrode SE1 may be formed to have a single-layer structure or a multi-layer structure.

The second connection electrode SE2 and the third connection electrode SE3 may be formed together with the first connection electrode SE1, may be in contact with the second active pattern ACT2 and the third active pattern ACT3, respectively, and may include a structure that is the same as or similar to the structure of the first connection electrode SE1.

The fourth insulating layer IL4 may cover the first to third connection electrodes SE1, SE2, and SE3 and may be disposed on the third insulating layer IL3. In an embodiment, the fourth insulating layer IL4 may include an insulating material. For example, the fourth insulating layer IL4 may include photoresist, polyacrylic resin, polyimide resin, acrylic resin, or the like.

The first pixel electrode AD1 may be disposed on the fourth insulating layer IL4. In an embodiment, the first pixel electrode AD1 may include a metal, an alloy, a conductive metal oxide, a transparent conductive material, or the like. For example, the first pixel electrode AD1 may include silver (Ag), an alloy containing silver, molybdenum (Mo), an alloy containing molybdenum, aluminum (Al), an alloy containing aluminum, aluminum nitride (AlN), tungsten (W), tungsten nitride (WN), copper (Cu), nickel (Ni), chromium (Cr), chromium nitride (CrN), titanium (Ti), tantalum (Ta), platinum (Pt), scandium (Sc), indium tin oxide (ITO), indium zinc oxide (IZO), or the like. These materials may be used alone or in combination with each other. Additionally, the first pixel electrode AD1 may be formed to have a single-layer structure or a multi-layer structure.

The second pixel electrode AD2 and the third pixel electrode AD3 may be formed together with the first pixel electrode AD1, and may include a structure that is the same as or similar to the structure of the first pixel electrode AD1. In an embodiment, the second pixel electrode AD2 may be spaced apart from the first pixel electrode AD1 in the first direction D1, and the third pixel electrode AD3 may be spaced apart from the second pixel electrode AD2 in the first direction D1.

The pixel defining layer PDL may be disposed on the fourth insulating layer IL4 and may cover end portions of the first pixel electrode AD1. In an embodiment, the pixel defining layer PDL may include an insulating material. For example, the pixel defining layer PDL may include a photoresist, a polyacrylic resin, a polyimide resin, an acrylic resin, or the like. In addition, the pixel defining layer PDL may further cover end portions of the second pixel electrode AD2 and end portions of the third pixel electrode AD3.

The first light-emitting layer EL1 may be disposed on the first pixel electrode AD1. In an embodiment, the first light-emitting layer EL1 may include an organic light-emitting material that emits the light when supplied with current. For example, the first light-emitting layer EL1 may emit the light corresponding to the driving current. In addition, the first light-emitting layer EL1 may further include an auxiliary layer such as a hole transport layer or an electron transport layer.

The second light-emitting layer EL2 and the third light-emitting layer EL3 may be formed together with the first light-emitting layer EL1, and may include a structure that is the same as or similar to the structure of the first light-emitting layer EL1. In an embodiment, the second light-emitting layer EL2 may be spaced apart from the first light-emitting layer EL1 in the first direction D1, and the third light-emitting layer EL3 may be spaced apart from the second light-emitting layer EL2 in the first direction D1.

For example, the first light-emitting layer EL1 may be a part of the first viewing angle adjustment pixel VPX1, the second light-emitting layer EL2 may be a part of the second viewing angle adjustment pixel VPX2, and the third light-emitting layer EL3 may be a part of the third viewing angle adjustment pixel VPX3.

The common electrode CT may be disposed on the first to third light-emitting layers EL1, EL2, and EL3. In an embodiment, the common electrode CT may include a metal, an alloy, a conductive metal oxide, a transparent conductive material, or the like. For example, the common electrode CT may include silver (Ag), an alloy containing silver, molybdenum (Mo), an alloy containing molybdenum, aluminum (Al), an alloy containing aluminum, aluminum nitride (AlN), tungsten (W), tungsten nitride (WN), copper (Cu), nickel (Ni), chromium (Cr), chromium nitride (CrN), titanium (Ti), tantalum (Ta), platinum (Pt), scandium (Sc), indium tin oxide (ITO), indium zinc oxide (IZO), or the like. These materials may be used alone or in combination with each other. In addition, the common electrode CT may be formed to have a single-layer structure or a multi-layer structure.

The encapsulation layer ENC may be disposed on the common electrode CT. The encapsulation layer ENC may prevent oxygen and/or moisture from penetrating into the first to third light-emitting layers EL1, EL2, and EL3. In an embodiment, the encapsulation layer ENC may be formed by alternately stacking inorganic layers and organic layers. That is, the encapsulation layer ENC may have a layered structure.

The sensing layer SL may be disposed on the encapsulation layer ENC. The sensing layer SL may detect a touch of a user. In an embodiment, the sensing layer SL may have a structure in which touch electrodes are stacked.

The planarization layer OC may be disposed on the sensing layer SL. The planarization layer OC may include an organic insulating material.

The first lens LS1 may be disposed on the planarization layer OC. In an embodiment, the first lens LS1 may overlap with the first light-emitting layer EL1. The first lens LS1 may change a path of the light emitted from the first light-emitting layer EL1 to be directed in the vertical direction (e.g., the fourth direction D4). For example, the first lens LS1 may have a first radius of curvature.

The second lens LS2 may be disposed on the planarization layer OC. In an embodiment, the second lens LS2 may overlap with the second light-emitting layer EL2. The second lens LS2 may change a path of the light emitted from the second light-emitting layer EL2 to be directed in the vertical direction (e.g., the fourth direction D4). For example, the second lens LS2 may have a second radius of curvature.

The third lens LS3 may be disposed on the planarization layer OC. In an embodiment, the third lens LS3 may overlap with the third light-emitting layer EL3. The third lens LS3 may change a path of the light emitted from the third light-emitting layer EL3 to be directed in the vertical direction (e.g., the fourth direction D4). For example, the third lens LS3 may have a third radius of curvature.

In an embodiment, the third radius of curvature may be smaller than the second radius of curvature, and the second radius of curvature may be smaller than the first radius of curvature. In other words, the curvature of the third lens LS3 may be larger than the curvature of the second lens LS2, and the curvature of the second lens LS2 may be larger than the curvature of the first lens LS1. Accordingly, the light gathering efficiency of the third lens LS3 may be larger than the light gathering efficiency of the second lens LS2, and the light gathering efficiency of the second lens LS2 may be larger than the light gathering efficiency of the first lens LS1.

The first light-blocking member BM1 may be disposed on the planarization layer OC and may be adjacent to the first lens LS1. The first light-blocking member BM1 may include a light-blocking material and may block a portion of the light emitted from the first light-emitting layer EL1. Accordingly, the viewing angle of the first viewing angle adjustment pixel VPX1 may be adjusted through the first lens LS1 and the first light-blocking member BM1.

The second light-blocking member BM2 may be disposed on the planarization layer OC and may be adjacent to the second lens LS2. The second light-blocking member BM2 may include a light-blocking material and may block a portion of the light emitted from the second light-emitting layer EL2. Accordingly, the viewing angle of the second viewing angle adjustment pixel VPX2 may be adjusted through the second lens LS2 and the second light-blocking member BM2.

The third light-blocking member BM3 may be disposed on the planarization layer OC and may be adjacent to the third lens LS3. The third light-blocking member BM3 may include a light-blocking material and may block a portion of the light emitted from the third light-emitting layer EL3. Accordingly, the viewing angle of the third viewing angle adjustment pixel VPX3 may be adjusted through the third lens LS3 and the third light-blocking member BM3.

The first light-blocking member BM1 may have a first width W1, the second light-blocking member BM2 may have a second width W2, and the third light-blocking member BM3 may have a third width W3. In an embodiment, the first width W1 may be smaller than the second width W2, and the second width W2 may be smaller than the third width W3.

In an embodiment, thicknesses of the first to third light-blocking members BM1, BM2, and BM3 may be the same as each other. In another embodiment, the thicknesses of the first to third light-blocking members BM1, BM2, and BM3 may be different from each other. For example, the thickness of the first light-blocking member BM1 may be smaller than the thickness of the second light-blocking member BM2, and the thickness of the second light-blocking member BM2 may be smaller than the thickness of the third light-blocking member BM3.

The first viewing angle adjustment pixel VPX1 may include the first lens LS1 having the first radius of curvature which is relatively large and the first light-blocking member BM1 having the first width W1 which is relatively small. Accordingly, the first luminance ratio R1 of the first viewing angle adjustment pixel VPX1 may be relatively large.

Additionally, the third viewing angle adjustment pixel VPX3 may include the third lens LS3 having the third radius of curvature which is relatively small and the third light-blocking member BM3 having the third width W3 which is relatively large. Accordingly, the third luminance ratio R3 of the third viewing angle adjustment pixel VPX3 may be relatively small.

Referring to FIG. 9B, a first lens LS1’ may be disposed on the planarization layer OC. In an embodiment, the first lens LS1’ may overlap with the first light-emitting layer EL1. The first lens LS1’ may change a path of the light emitted from the first light-emitting layer EL1 to be directed in the vertical direction (e.g., the fourth direction D4).

A second lens LS2’ may be disposed on the planarization layer OC. In an embodiment, the second lens LS2’ may overlap with the second light-emitting layer EL2. The second lens LS2’ may change a path of the light emitted from the second light-emitting layer EL2 to be directed in the vertical direction (e.g., the fourth direction D4).

A third lens LS3’ may be disposed on the planarization layer OC. In an embodiment, the third lens LS3’ may overlap with the third light-emitting layer EL3. The third lens LS3’ may change a path of the light emitted from the third light-emitting layer EL3 to be directed in the vertical direction (e.g., the fourth direction D4).

In an embodiment, a height of the first lens LS1’, a height of the second lens LS2’, and a height of the third lens LS3’ may be substantially equal to each other. In addition, a width of the first lens LS1’ may be larger than a width of the second lens LS2’, and the width of the second lens LS2’ may be larger than a width of the third lens LS3’.

Referring to FIG. 10, the display device DD1 may further include first to third normal active patterns CACT1, CACT2, and CACT3, first to third normal gate electrodes CGAT1, CGAT2, and CGAT3, first to third normal capacitor electrodes CCE1, CCE2, and CCE3, first to third normal connection electrodes CSE1, CSE2, and CSE3, first to third normal pixel electrodes CAD1, CAD2, and CAD3, and first to third normal light-emitting layers CEL1, CEL2, and CEL3.

The first to third normal active patterns CACT1, CACT2, and CACT3 may be formed together with the first active pattern ACT1, and may include a structure that is the same as or similar to the structure of the first active pattern ACT1.

The first to third normal gate electrodes CGAT1, CGAT2, and CGAT3 may be formed together with the first gate electrode GAT1, may overlap with the first to third normal active patterns CACT1, CACT2, and CACT3, respectively, and may include a structure that is the same as or similar to the structure of the first gate electrode GAT1.

The first to third normal capacitor electrodes CCE1, CCE2, and CCE3 may be formed together with the first capacitor electrode CE1, may overlap with the first to third normal gate electrodes CGAT1, CGAT2, and CGAT3, respectively, and may include a structure that is the same as or similar to the structure of the first capacitor electrode CE1.

The first to third normal connection electrodes CSE1, CSE2, and CSE3 may be formed together with the first connection electrode SE1, may be in contact (e.g., direct contact) with the first to third normal active patterns CACT1, CACT2, and CACT3, respectively, and may include a structure that is the same as or similar to the structure of the first connection electrode SE1.

The first to third normal pixel electrodes CAD1, CAD2, and CAD3 may be formed together with the first pixel electrode AD1, and may include a structure that is the same as or similar to the structure of the first pixel electrode AD1. In an embodiment, the second normal pixel electrode CAD2 may be spaced apart from the first normal pixel electrode CAD1 in the first direction D1, and the third normal pixel electrode CAD3 may be spaced apart from the second normal pixel electrode CAD2 in the first direction D1.

The first to third normal light-emitting layers CEL1, CEL2, and CEL3 may be formed together with the first light-emitting layer EL1, and may include a structure that is the same as or similar to the structure of the first light-emitting layer EL1. In an embodiment, the second normal light-emitting layer CEL2 may be spaced apart from the first normal light-emitting layer CEL1 in the first direction D1, and the third normal light-emitting layer CEL3 may be spaced apart from the second normal light-emitting layer CEL2 in the first direction D1.

As illustrated in FIGS. 8, 9A, and 10, the first pixel electrode AD1 and the first light-emitting layer EL1 may constitute a portion of the first viewing angle adjustment pixel VPX1, and the first normal pixel electrode CAD1 and the first normal light-emitting layer CEL1 may constitute a portion of the first normal pixel CPX1.

In an embodiment, the first normal pixel electrode CAD1 may be adjacent to the first pixel electrode AD1, and the first normal light-emitting layer CEL1 may be adjacent to the first light-emitting layer EL1.

The second pixel electrode AD2 and the second light-emitting layer EL2 may constitute a portion of the second viewing angle adjustment pixel VPX2, and the second normal pixel electrode CAD2 and the second normal light-emitting layer CEL2 may constitute a portion of the second normal pixel CPX2.

In an embodiment, the second normal pixel electrode CAD2 may be adjacent to the second pixel electrode AD2, and the second normal light-emitting layer CEL2 may be adjacent to the second light-emitting layer EL2.

The third pixel electrode AD3 and the third light-emitting layer EL3 may constitute portion of the third viewing angle adjustment pixel VPX3, and the third normal pixel electrode CAD3 and the third normal light-emitting layer CEL3 may constitute portion of the third normal pixel CPX3.

In an embodiment, the third normal pixel electrode CAD3 may be adjacent to the third pixel electrode AD3, and the third normal light-emitting layer CEL3 may be adjacent to the third light-emitting layer EL3.

In an embodiment, no lens may be disposed on the first to third normal light-emitting layers CEL1, CEL2, and CEL3. In addition, no light-blocking member may be disposed on the first to third normal light-emitting layers CEL1, CEL2, and CEL3.

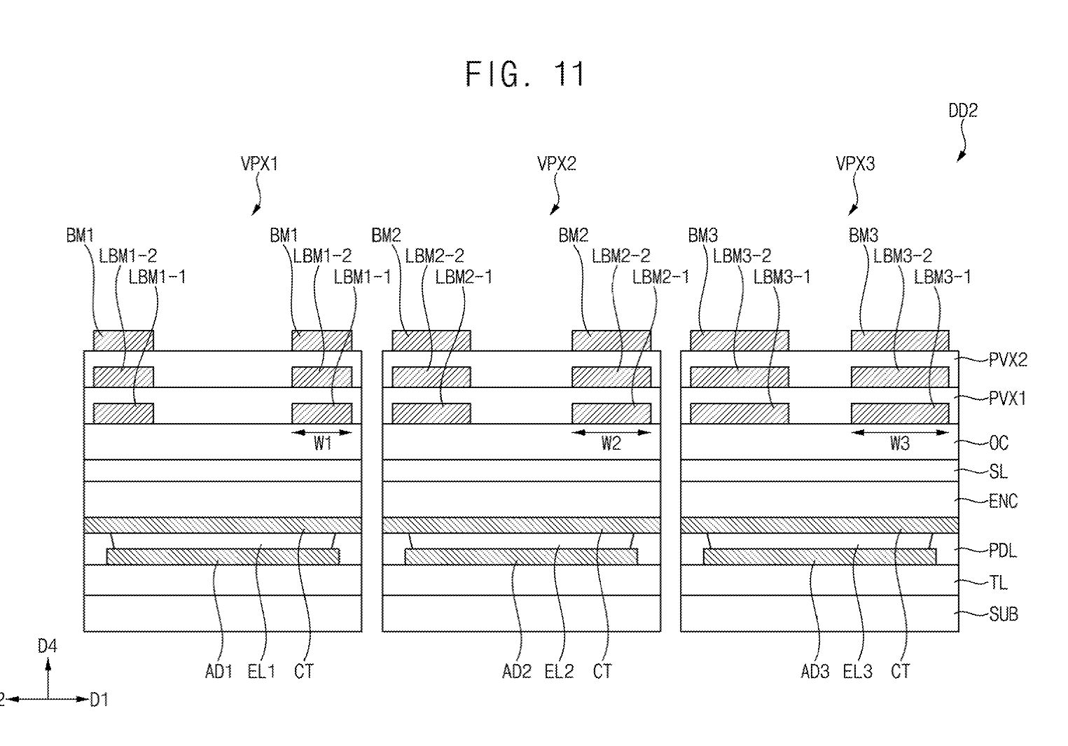

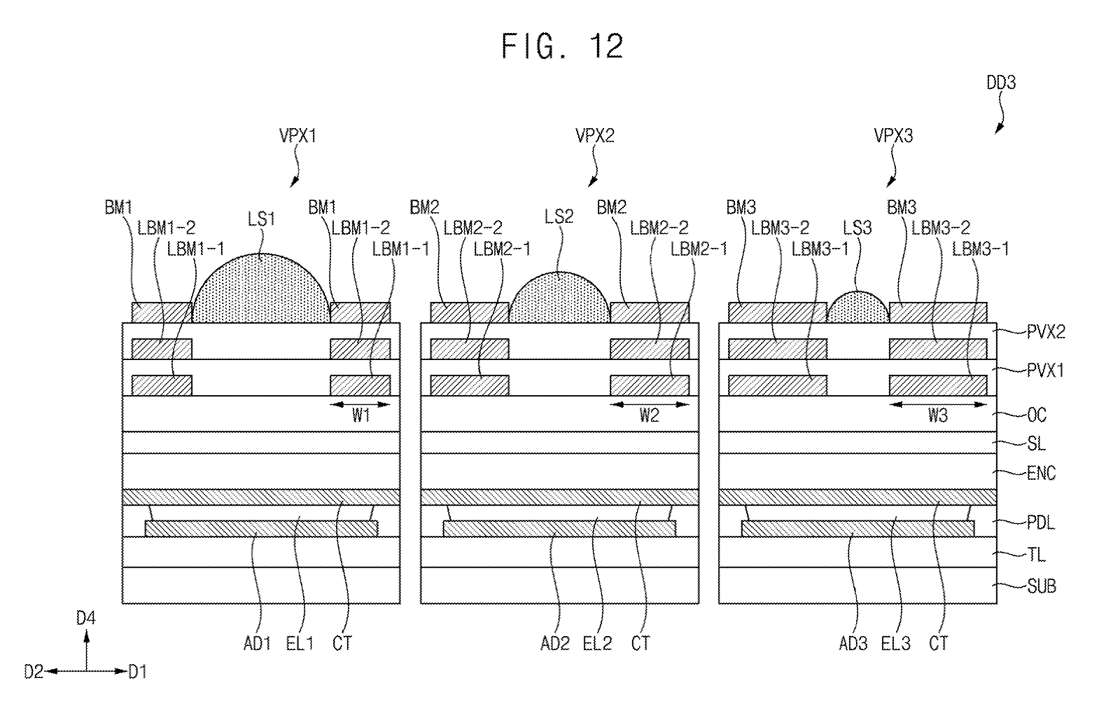

FIG. 11 is a cross-sectional view illustrating viewing angle adjustment pixels included in a display device according to an embodiment.

Referring to FIG. 11, the display device DD2 may not include a lens. The display device DD2 may be substantially the same as the display device DD1 described above with reference to FIG. 9A, except for a first-first lower light-blocking member LBM1-1, a first-second lower light-blocking member LBM1-2, a second-first lower light-blocking member LBM2-1, a second-second lower light-blocking member LBM2-2, a third-first lower light-blocking member LBM3-1, a third-second lower light-blocking member LBM3-2, a first protective layer PVX1, and a second protective layer PVX2.

The first-first lower light-blocking member LBM1-1 may be disposed on the planarization layer OC. The first-first lower light-blocking member LBM1-1 may include a light-blocking material and may block a portion of the light emitted from the first light-emitting layer EL1.

The second-first lower light-blocking member LBM2-1 may be disposed on the planarization layer OC. The second-first lower light-blocking member LBM2-1 may include a light-blocking material and may block a portion of the light emitted from the second light-emitting layer EL2.

The third-first lower light-blocking member LBM3-1 may be disposed on the planarization layer OC. The third-first lower light-blocking member LBM3-1 may include a light-blocking material and may block a portion of the light emitted from the third light-emitting layer EL3.

The first protective layer PVX1 may cover the first-first, second-first, and third-first lower light-blocking members LBM1-1, LBM2-1, and LBM3-1.

The first-second lower light-blocking member LBM1-2 may be disposed on the first protective layer PVX1. The first-second lower light-blocking member LBM1-2 may include a light-blocking material and may block a portion of the light emitted from the first light-emitting layer EL1.

The second-second lower light-blocking member LBM2-2 may be disposed on the first protective layer PVX1. The second-second lower light-blocking member LBM2-2 may include a light-blocking material and may block a portion of the light emitted from the second light-emitting layer EL2.

The third-second lower light-blocking member LBM3-2 may be disposed on the first protective layer PVX1. The third-second lower light-blocking member LBM3-2 may include a light-blocking material and may block a portion of the light emitted from the third light-emitting layer EL3.

The second protective layer PVX2 may cover the first-second, second-second, and third-second light-blocking members LBM1-2, LBM2-2, and LBM3-2.

The first light-blocking member BM1 may be disposed on the second protective layer PVX2. The first light-blocking member BM1 may include a light-blocking material and may block a portion of the light emitted from the first light-emitting layer EL1.

The second light-blocking member BM2 may be disposed on the second protective layer PVX2. The second light-blocking member BM2 may include a light-blocking material and may block a portion of the light emitted from the second light-emitting layer EL2.

The third light-blocking member BM3 may be disposed on the second protective layer PVX2. The third light-blocking member BM3 may include a light-blocking material and may block a portion of the light emitted from the third light-emitting layer EL3.

The first-first lower light-blocking member LBM1-1, the first-second lower light-blocking member LBM1-2, and the first light-blocking member BM1 may overlap with each other and may have the first width W1.

The second-first lower light-blocking member LBM2-1, the second-second lower light-blocking member LBM2-2, and the second light-blocking member BM2 may overlap with each other and may have the second width W2.

The third-first lower light-blocking member LBM3-1, the third-second lower light-blocking member LBM3-2, and the third light-blocking member BM3 may overlap with each other and may have the third width W3.

In an embodiment, the first width W1 may be smaller than the second width W2, and the second width W2 may be smaller than the third width W3.

The first viewing angle adjustment pixel VPX1 may include the first-first lower light-blocking member LBM1-1, the first-second lower light-blocking member LBM1-2, and the first light-blocking member BM1 that are stacked (or laminated) and have the first width W1, which may be relatively small. Accordingly, the first luminance ratio R1 of the first viewing angle adjustment pixel VPX1 may be relatively large.

The third viewing angle adjustment pixel VPX3 may include the third-first lower light-blocking member LBM3-1, the third-second lower light-blocking member LBM3-2, and the third light-blocking member BM3 that are stacked and have the third width W3, which may be relatively large. Accordingly, the third luminance ratio R3 of the third viewing angle adjustment pixel VPX3 may be relatively small.

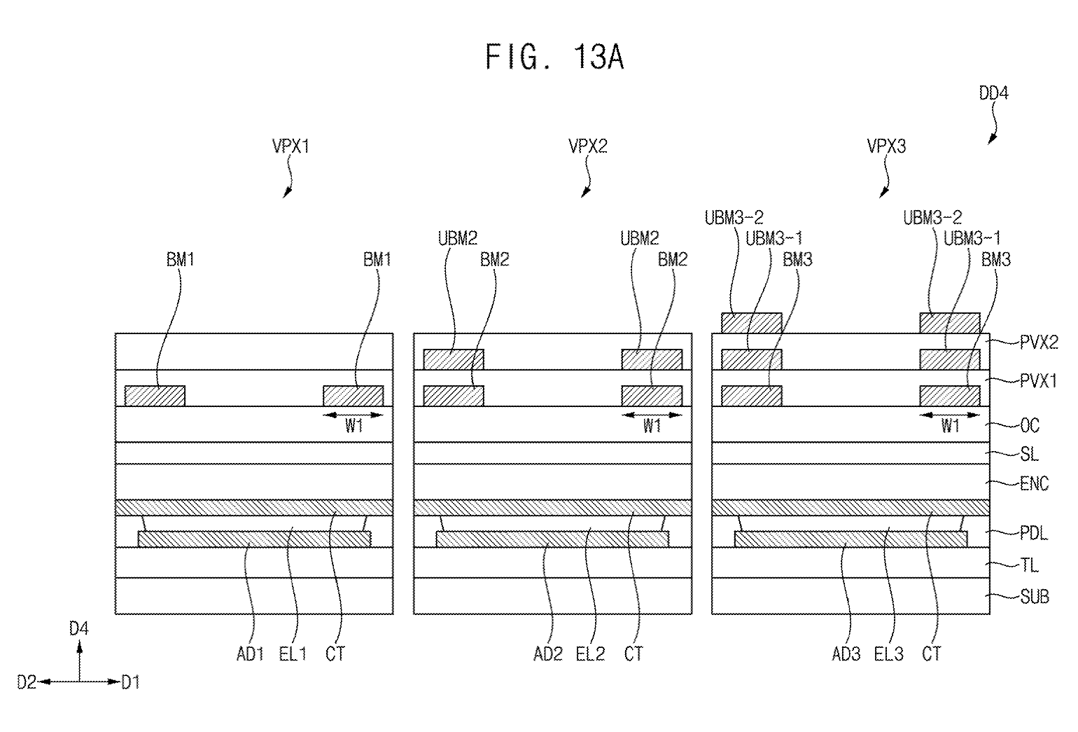

FIG. 12 is a cross-sectional view illustrating viewing angle adjustment pixels included in a display device according to an embodiment.

Referring to FIG. 12, the display device DD3 may be substantially the same as the display device DD2 described above with reference to FIG. 11, except for a first lens LS1, a second lens LS2, and a third lens LS3.

The first lens LS1 may be disposed on the second protective layer PVX2. In an embodiment, the first lens LS1 may overlap with the first light-emitting layer EL1. The first lens LS1 may change a path of the light emitted from the first light-emitting layer EL1 to be directed in the vertical direction (e.g., the fourth direction D4). For example, the first lens LS1 may have a first radius of curvature.

The second lens LS2 may be disposed on the second protective layer PVX2. In an embodiment, the second lens LS2 may overlap with the second light-emitting layer EL2. The second lens LS2 may change a path of the light emitted from the second light-emitting layer EL2 to be directed in the vertical direction (e.g., the fourth direction D4). For example, the second lens LS2 may have a second radius of curvature.

The third lens LS3 may be disposed on the second protective layer PVX2. In an embodiment, the third lens LS3 may overlap with the third light-emitting layer EL3. The third lens LS3 may change a path of the light emitted from the third light-emitting layer EL3 to be directed in the vertical direction (e.g., the fourth direction D4). For example, the third lens LS3 may have a third radius of curvature.

In an embodiment, the third radius of curvature may be smaller than the second radius of curvature, and the second radius of curvature may be smaller than the first radius of curvature. In other words, the curvature of the third lens LS3 may be larger than the curvature of the second lens LS2, and the curvature of the second lens LS2 may be larger than the curvature of the first lens LS1. Accordingly, the light gathering efficiency of the third lens LS3 may be larger than the light gathering efficiency of the second lens LS2, and the light gathering efficiency of the second lens LS2 may be larger than the light gathering efficiency of the first lens LS1.

The first viewing angle adjustment pixel VPX1 may include the first-first lower light-blocking member LBM1-1, the first-second lower light-blocking member LBM1-2, and the first light-blocking member BM1 that are stacked (or laminated) and have the first width W1, which may be relatively small. In addition, the first viewing angle adjustment pixel VPX1 may include the first lens LS1 having the first radius of curvature, which may be relatively large. Accordingly, the first luminance ratio R1 of the first viewing angle adjustment pixel VPX1 may be relatively large.

The third viewing angle adjustment pixel VPX3 may include the third-first lower light-blocking member LBM3-1, the third-second lower light-blocking member LBM3-2, and the third light-blocking member BM3 that are stacked and have the third width W3, which may be relatively large. In addition, the third viewing angle adjustment pixel VPX3 may include the third lens LS3 having the third radius of curvature, which may be relatively small. Accordingly, the third luminance ratio R3 of the third viewing angle adjustment pixel VPX3 may be relatively small.

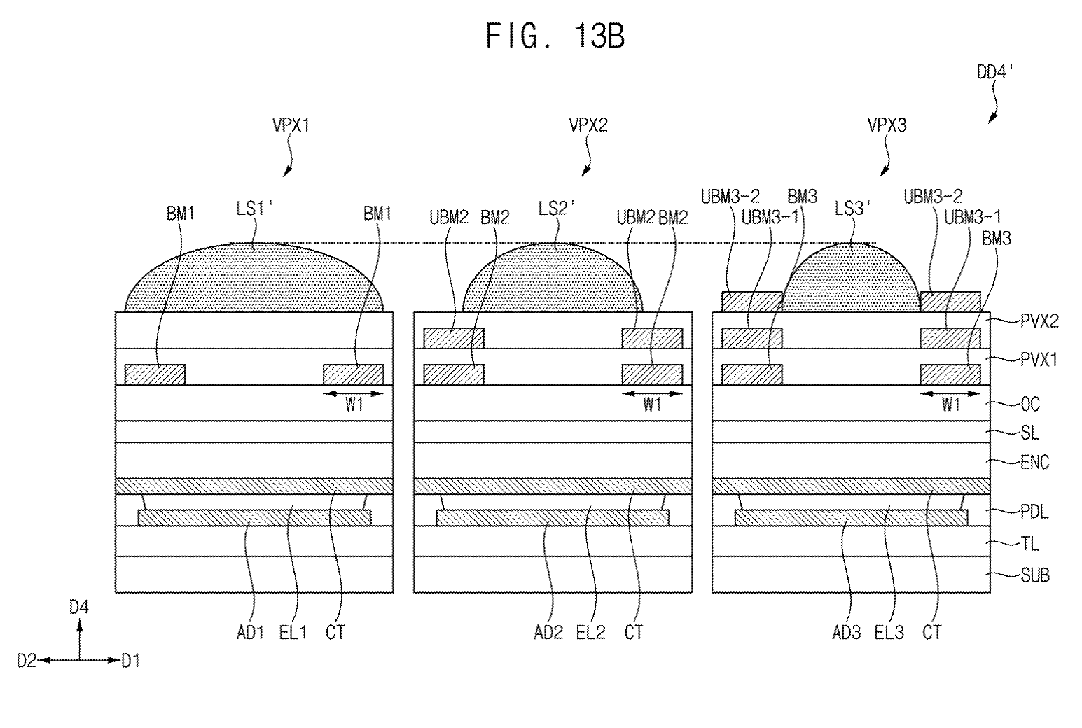

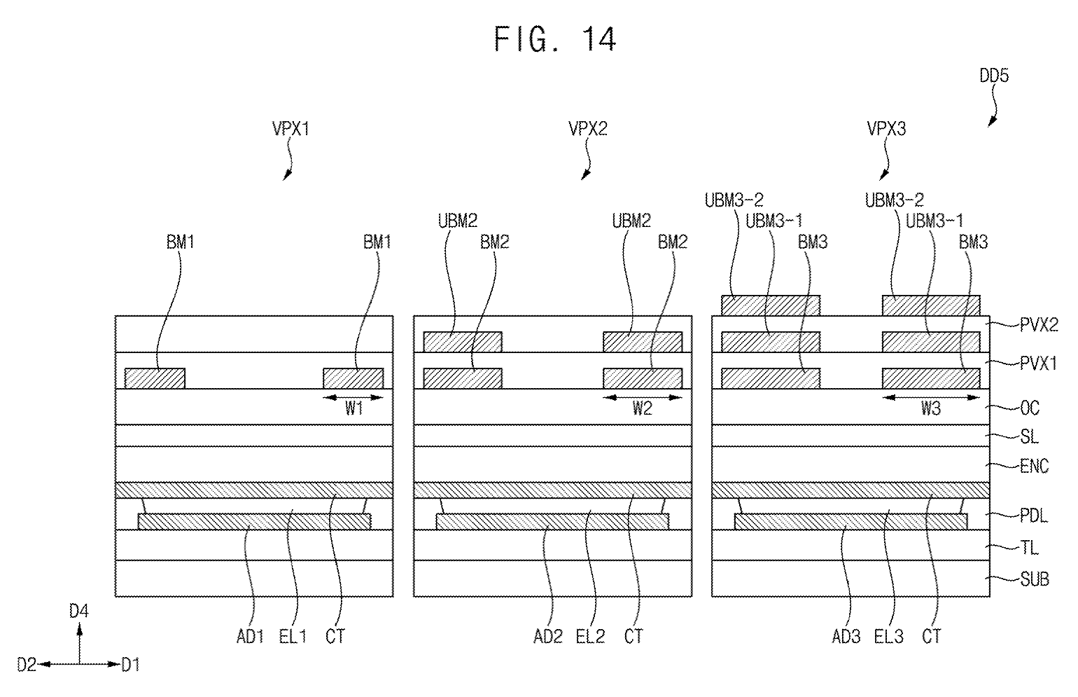

FIG. 13A is a cross-sectional view illustrating an example of viewing angle adjustment pixels included in a display device according to an embodiment, and FIG. 13B is a cross-sectional view illustrating another example of viewing angle adjustment pixels included in a display device according to an embodiment.

Referring to FIG. 13A, the display device DD4 may not include a lens. The display device DD4 may be substantially the same as the display device DD1 described above with reference to FIG. 9A, except for a second upper light-blocking member UBM2, a third-first upper light-blocking member UBM3-1, a third-second upper light-blocking member UBM3-2, a first protective layer PVX1, and a second protective layer PVX2.

The first protective layer PVX1 may cover the first to third light-blocking members BM1, BM2, and BM3.

The second upper light-blocking member UBM2 may be disposed on the first protective layer PVX1 and may overlap with the second light-blocking member BM2. The second upper light-blocking member UBM2 may include a light-blocking material and may block a portion of the light emitted from the second light-emitting layer EL2.

The third-first upper light-blocking member UBM3-1 may be disposed on the first protective layer PVX1 and may overlap with the third light-blocking member BM3. The third-first upper light-blocking member UBM3-1 may include a light-blocking material and may block a portion of the light emitted from the third light-emitting layer EL3.

The second protective layer PVX2 may cover the second upper light-blocking member UBM2 and the third-first upper light-blocking member UBM3-1.

The third-second upper light-blocking member UBM3-2 may be disposed on the second protective layer PVX2 and may overlap with the third-first upper light-blocking member UBM3-1. The third-second upper light-blocking member UBM3-2 may include a light-blocking material and may block a portion of the light emitted from the third light-emitting layer EL3.

The first light-blocking member BM1 may have the first width W1.

The second light-blocking member BM2 and the second upper light-blocking member UBM2 may have the first width W1.

The third light-blocking member BM3, the third-first upper light-blocking member UBM3-1, and the third-second upper light-blocking member UBM3-2 may have the first width W1.

As illustrated in FIG. 13A, the number of light-blocking members vertically stacked on the first light-emitting layer EL1 may be smaller than the number of light-blocking members vertically stacked on the second light-emitting layer EL2. In addition, the number of light-blocking members vertically stacked on the second light-emitting layer EL2 may be smaller than the number of light-blocking members vertically stacked on the third light-emitting layer EL3.

For example, the number of the light-blocking members vertically stacked on the first light-emitting layer EL1 may be 1, the number of the light-blocking members vertically stacked on the second light-emitting layer EL2 may be 2, and the number of the light-blocking members vertically stacked on the third light-emitting layer EL3 may be 3.

In other words, a light-blocking member may not be disposed on the first light-blocking member BM1, a light-blocking member may not be disposed on the second upper light-blocking member UBM2, and a light-blocking member may not be disposed on the third-second upper light-blocking member UBM3-2.

The first viewing angle adjustment pixel VPX1 may include the relatively small number of vertically stacked light-blocking members. Accordingly, the first luminance ratio R1 of the first viewing angle adjustment pixel VPX1 may be relatively large.

The third viewing angle adjustment pixel VPX3 may include the relatively large number of vertically stacked light-blocking members. Accordingly, the third luminance ratio R3 of the third viewing angle adjustment pixel VPX3 may be relatively small.

Referring to FIG. 13B, the display device DD4’ may include a lens. For example, the display device DD4’ may include a first lens LS1’, a second lens LS2’, and a third lens LS3’. However, the display device DD4’ may be substantially the same as the display device DD4 described above, except for the first lens LS1’, the second lens LS2’, and the third lens LS3’.

The first lens LS1’ may be disposed on the planarization layer OC. In an embodiment, the first lens LS1’ may overlap with the first light-emitting layer EL1. The first lens LS1’ may change a path of the light emitted from the first light-emitting layer EL1 to be directed in the vertical direction (e.g., the fourth direction D4). For example, the first lens LS1’ may have a first radius of curvature.

The second lens LS2’ may be disposed on the planarization layer OC. In an embodiment, the second lens LS2’ may overlap with the second light-emitting layer EL2. The second lens LS2’ may change a path of the light emitted from the second light-emitting layer EL2 to be directed in the vertical direction (e.g., the fourth direction D4). For example, the second lens LS2’ may have a second radius of curvature.

The third lens LS3’ may be disposed on the planarization layer OC. In an embodiment, the third lens LS3’ may overlap with the third light-emitting layer EL3. The third lens LS3’ may change a path of the light emitted from the third light-emitting layer EL3 to be directed in the vertical direction (e.g., the fourth direction D4). For example, the third lens LS3’ may have a third radius of curvature.

In an embodiment, the third radius of curvature may be smaller than the second radius of curvature, and the second radius of curvature may be smaller than the first radius of curvature. In other words, the curvature of the third lens LS3’ may be larger than the curvature of the second lens LS2’, and the curvature of the second lens LS2’ may be larger than the curvature of the first lens LS1’. Accordingly, the light gathering efficiency of the third lens LS3’ may be larger than the light gathering efficiency of the second lens LS2’, and the light gathering efficiency of the second lens LS2’ may be larger than the light gathering efficiency of the first lens LS1’.

In an embodiment, the height of the first lens LS1’, the height of the second lens LS2’, and the height of the third lens LS3’ may be substantially equal to each other. In addition, the width of the first lens LS1’ may be larger than the width of the second lens LS2’, and the width of the second lens LS2’ may be larger than the width of the third lens LS3’.

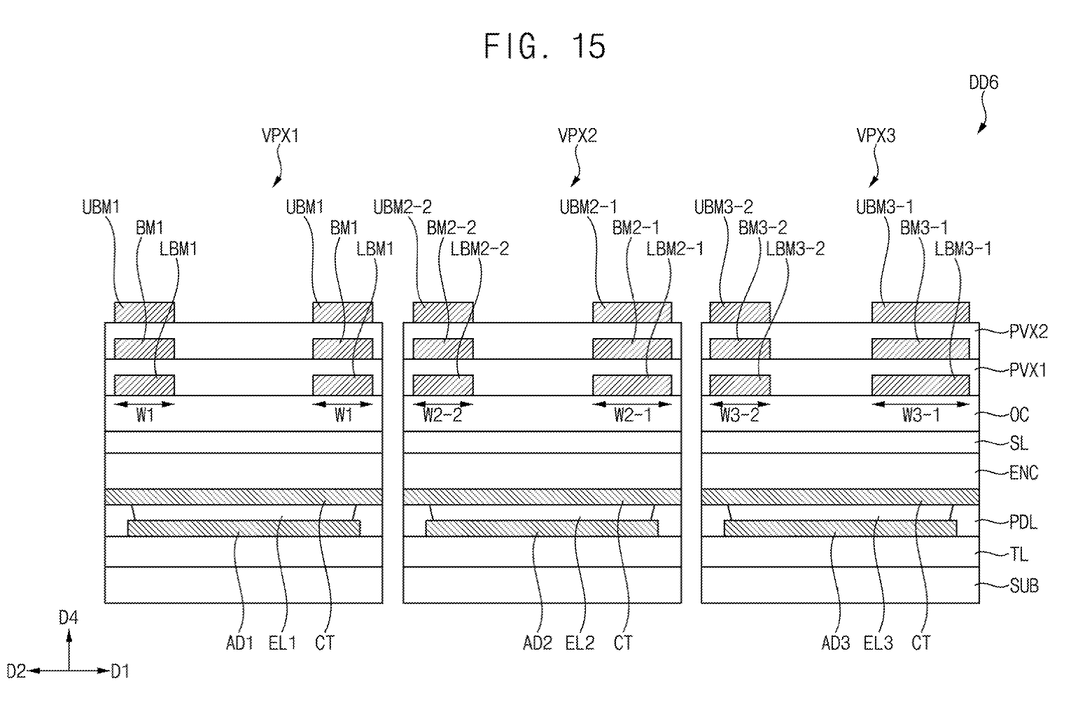

FIG. 14 is a cross-sectional view illustrating viewing angle adjustment pixels included in a display device according to an embodiment.

Referring to FIG. 14, the display device DD5 may be substantially the same as the display device DD4 described above with reference to FIG. 13A, except for the width of each of the light-blocking members.

The first light-blocking member BM1 may have a first width W1.

The second light-blocking member BM2 and the second upper light-blocking member UBM2 may have a second width W2 larger than the first width W1.

The third light-blocking member BM3, the third-first upper light-blocking member UBM3-1, and the third-second upper light-blocking member UBM3-2 may have a third width W3 larger than the second width W2.

The first viewing angle adjustment pixel VPX1 may include a relatively small number of vertically stacked light-blocking members, and the width of the light-blocking members may be relatively small. Accordingly, the first luminance ratio R1 of the first viewing angle adjustment pixel VPX1 may be relatively large.

The third viewing angle adjustment pixel VPX3 may include a relatively large number of vertically stacked light-blocking members, and the width of the light-blocking members may be relatively large. Accordingly, the third luminance ratio R3 of the third viewing angle adjustment pixel VPX3 may be relatively small.

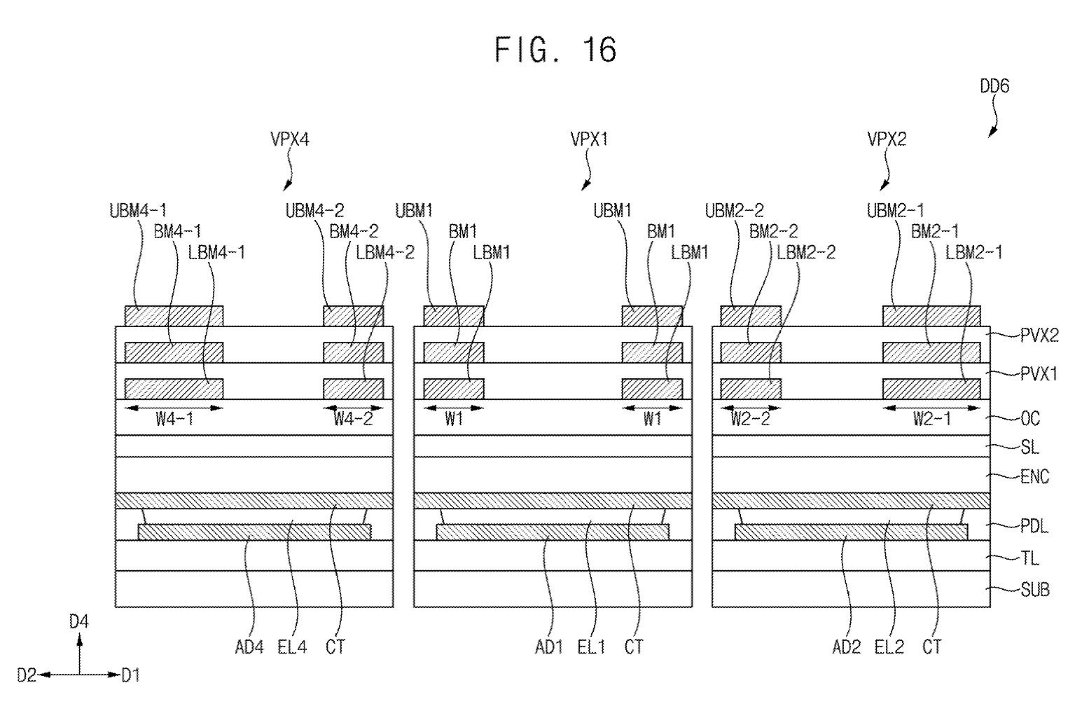

FIGS. 15 and 16 are cross-sectional views illustrating viewing angle adjustment pixels included in a display device according to an embodiment.

Referring to FIGS. 15 and 16, the display device DD6 may include a first lower light-blocking member LBM1, a second-first lower light-blocking member LBM2-1, a second-second lower light-blocking member LBM2-2, a third-first lower light-blocking member LBM3-1, a third-second lower light-blocking member LBM3-2, a fourth-first lower light-blocking member LBM4-1, a fourth-second lower light-blocking member LBM4-2, a first protective layer PVX1, a first light-blocking member BM1, a second-first light-blocking member BM2-1, a second-second light-blocking member BM2-2, a third-first light-blocking member BM3-1, a third-second light-blocking member BM3-2, a fourth-first light-blocking member BM4-1, a fourth-second light-blocking member BM4-2, a second protective layer PVX2, a first upper light-blocking member UBM1, a second-first upper light-blocking member UBM2-1, a second-second upper light-blocking member UBM2-2, a third-first upper light-blocking member UBM3-1, a third-second upper light-blocking member UBM3-2., a fourth-first upper light-blocking member UBM4-1, and a fourth-second upper light-blocking member UBM4-2.

The first lower light-blocking member LBM1 may be disposed on the first light-emitting layer EL1. The first light-blocking member BM1 may be disposed on the first lower light-blocking member LBM1 and may overlap with the first lower light-blocking member LBM1. The first upper light-blocking member UBM1 may be disposed on the first light-blocking member BM1 and may overlap with the first light-blocking member BM1.

The first lower light-blocking member LBM1, the first light-blocking member BM1, and the first upper light-blocking member UBM1 may have a first width W1.

The second light-emitting layer EL2 may be spaced apart from the first light-emitting layer EL1 in the first direction D1.

The second-first lower light-blocking member LBM2-1 may be disposed on the second light-emitting layer EL2. The second-first light-blocking member BM2-1 may be disposed on the second-first lower light-blocking member LBM2-1 and may overlap with the second-first lower light-blocking member LBM2-1. The second-first upper light-blocking member UBM2-1 may be disposed on the second-first light-blocking member BM2-1 and may overlap with the second-first light-blocking member BM2-1.

The second-first lower light-blocking member LBM2-1, the second-first light-blocking member BM2-1, and the second-first upper light-blocking member UBM2-1 may have a second-first width W2-1.

The second-second lower light-blocking member LBM2-2 may be disposed on the second light-emitting layer EL2 and may be located between the first lower light-blocking member LBM1 and the second-first lower light-blocking member LBM2-1. The second-second light-blocking member BM2-2 may be disposed on the second-second lower light-blocking member LBM2-2 and may overlap with the second-second lower light-blocking member LBM2-2. The second-second upper light-blocking member UBM2-2 may be disposed on the second-second light-blocking member BM2-2 and may overlap with the second-second light-blocking member BM2-2.

The second-second lower light-blocking member LBM2-2, the second-second light-blocking member BM2-2, and the second-second upper light-blocking member UBM2-2 may have a second-second width W2-2.

In an embodiment, the second-second width W2-2 may be smaller than the second-first width W2-1. Additionally, the second-first width W2-1 may be larger than the first width W1.

The third light-emitting layer EL3 may be spaced apart from the second light-emitting layer EL2 in the first direction D1.

The third-first lower light-blocking member LBM3-1 may be disposed on the third light-emitting layer EL3. The third-first light-blocking member BM3-1 may be disposed on the third-first lower light-blocking member LBM3-1 and may overlap with the third-first lower light-blocking member LBM3-1. The third-first upper light-blocking member UBM3-1 may be disposed on the third-first light-blocking member BM3-1 and may overlap with the third-first light-blocking member BM3-1.

The third-first lower light-blocking member LBM3-1, the third-first light-blocking member BM3-1, and the third-first upper light-blocking member UBM3-1 may have a third-first width W3-1.

The third-second lower light-blocking member LBM3-2 may be disposed on the third light-emitting layer EL3 and may be located between the second-first lower light-blocking member LBM2-1 and the third-first lower light-blocking member LBM3-1. The third-second light-blocking member BM3-2 may be disposed on the third-second lower light-blocking member LBM3-2 and may overlap with the third-second lower light-blocking member LBM3-2. The third-second upper light-blocking member UBM3-2 may be disposed on the third-second light-blocking member BM3-2 and may overlap with the third-second light-blocking member BM3-2.

The third-second lower light-blocking member LBM3-2, the third-second light-blocking member BM3-2, and the third-second upper light-blocking member UBM3-2 may have a third-second width W3-2.

In an embodiment, the third-second width W3-2 may be smaller than the third-first width W3-1. Additionally, the third-first width W3-1 may be larger than the second-first width W2-1.

A fourth pixel electrode AD4 may be spaced apart from the first pixel electrode AD1 in the second direction D2, and a fourth light-emitting layer EL4 may be spaced apart from the first light-emitting layer EL1 in the second direction D2.

The fourth-first lower light-blocking member LBM4-1 may be disposed on the fourth light-emitting layer EL4. The fourth-first light-blocking member BM4-1 may be disposed on the fourth-first lower light-blocking member LBM4-1 and may overlap with the fourth-first lower light-blocking member LBM4-1. The fourth-first upper light-blocking member UBM4-1 may be disposed on the fourth-first light-blocking member BM4-1 and may overlap with the fourth-first light-blocking member BM4-1.

The fourth-first lower light-blocking member LBM4-1, the fourth-first light-blocking member BM4-1, and the fourth-first upper light-blocking member UBM4-1 may have a fourth-first width W4-1.

The fourth-second lower light-blocking member LBM4-2 may be disposed on the fourth light-emitting layer EL4 and may be located between the first lower light-blocking member LBM1 and the fourth-first lower light-blocking member LBM4-1. The fourth-second light-blocking member BM4-2 may be disposed on the fourth-second lower light-blocking member LBM4-2 and may overlap with the fourth-second lower light-blocking member LBM4-2. The fourth-second upper light-blocking member UBM4-2 may be disposed on the fourth-second light-blocking member BM4-2 and may overlap with the fourth-second light-blocking member BM4-2.

The fourth-second lower light-blocking member LBM4-2, the fourth-second light-blocking member BM4-2, and the fourth-second upper light-blocking member UBM4-2 may have a fourth-second width W4-2.

In an embodiment, the fourth-second width W4-2 may be smaller than the fourth-first width W4-1. Additionally, the fourth-first width W4-1 may be larger than the first width W1.

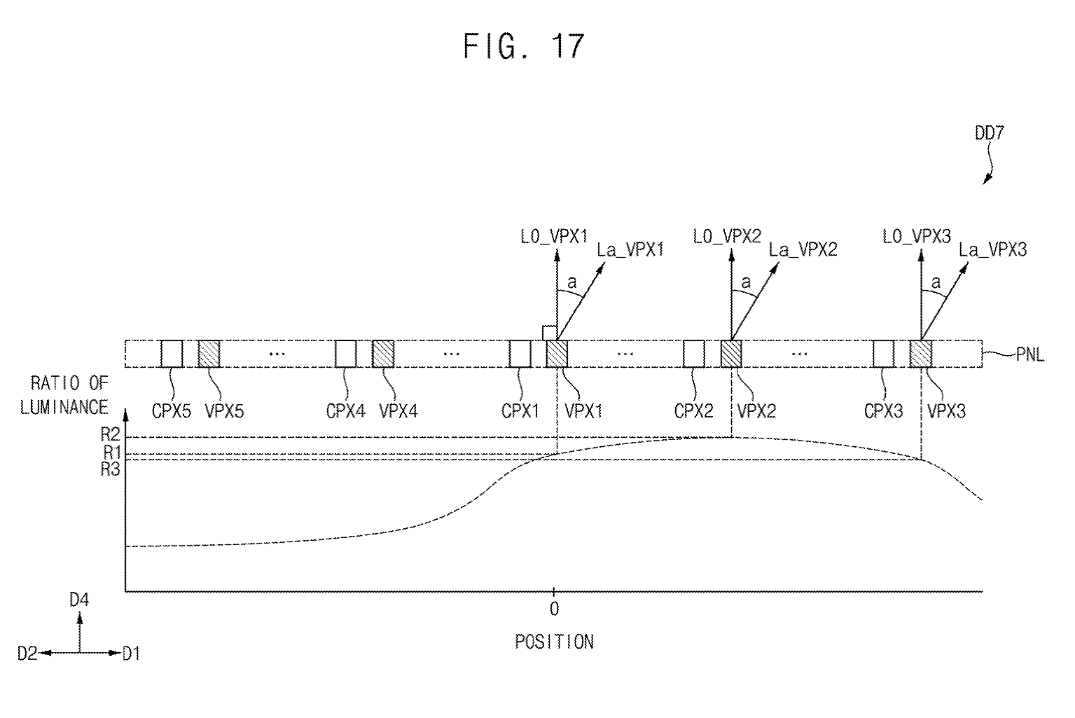

FIG. 17 is a graph for describing an intensity of light measured at a front of a display device according to an embodiment while the display device is driven in a normal mode or in a viewing angle adjustment mode.

Referring to FIG. 17, a display device DD7 may include a plurality of viewing angle adjustment pixels, and a luminance ratio may be defined for each of the viewing angle adjustment pixels. As described above, the luminance ratio may be defined as a ratio of a luminance of the side light to a luminance of the front light.

The viewing angle adjustment pixel having the highest luminance ratio may be appropriately set as required.

For example, the first viewing angle adjustment pixel VPX1 may be located at the central region of the display panel PNL, the second viewing angle adjustment pixel VPX2 may be spaced apart from the first viewing angle adjustment pixel VPX1 in the first direction D1, and the third viewing angle adjustment pixel VPX3 may be spaced apart from the second viewing angle adjustment pixel VPX2 in the first direction D1.

In an embodiment, as illustrated in FIG. 4, the first luminance ratio R1 of the first viewing angle adjustment pixel VPX1 may be larger than the second luminance ratio R2 of the second viewing angle adjustment pixel VPX2, and the second luminance ratio R2 of the second viewing angle adjustment pixel VPX2 may be larger than the third luminance ratio R3 of the third viewing angle adjustment pixel VPX3. That is, the luminance ratio of the first viewing angle adjustment pixel VPX1 located at the central region of the display panel PNL may be the largest.

In another embodiment, as illustrated in FIG. 17, the second luminance ratio R2 of the second viewing angle adjustment pixel VPX2 may be larger than the first luminance ratio R1 of the first viewing angle adjustment pixel VPX1, and the first luminance ratio R1 of the first viewing angle adjustment pixel VPX1 may be larger than the third luminance ratio R3 of the third viewing angle adjustment pixel VPX3. That is, the luminance ratio of the second viewing angle adjustment pixel VPX2 located between the central region and the peripheral region of the display panel PNL may be the largest.

The display device according to embodiments may be applied to various electronic devices. An electronic device according to embodiments may include the display devices described above and may further include a module or device having additional functions in addition to the display devices.

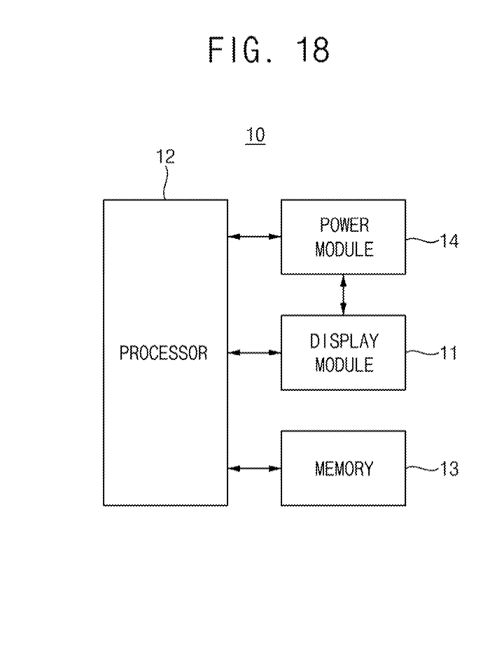

FIG. 18 is a block diagram illustrating an electronic device according to embodiments.

Referring to FIG. 18, an electronic device 10 may include a display module 11, at least one processor 12, a memory 13, and a power module 14.

The at least one processor 12 may include at least one from among a central processing unit (CPU), an application processor (AP), a graphic processing unit (GPU), a communication processor (CP), an image signal processor (ISP), and a controller.

The memory 13 may store data information for the operation of the at least one processor 12 or the display module 11. When the at least one processor 12 executes an application stored in the memory 13, the at least one processor 12 may transmit an image data signal and/or an input control signal to the display module 11, and the display module 11 may process the received signal to output image information through a display screen.

The power module 14 may include a power supply module such as a power adapter, a battery device, or the like and a power conversion module that converts power supplied by the power supply module to generate power for the operation of the electronic device 10.

At least one of the components of the electronic device 10 described above may be included in the display device according to embodiments described above. In addition, some of individual modules functionally included in one module may be included in the display device, while others may be provided separately from the display device. For example, the display device may include a display module 11, and the at least one processor 12, the memory 13, and the power module 14 may be provided in the form of other devices within the electronic device 10 other than the display device.

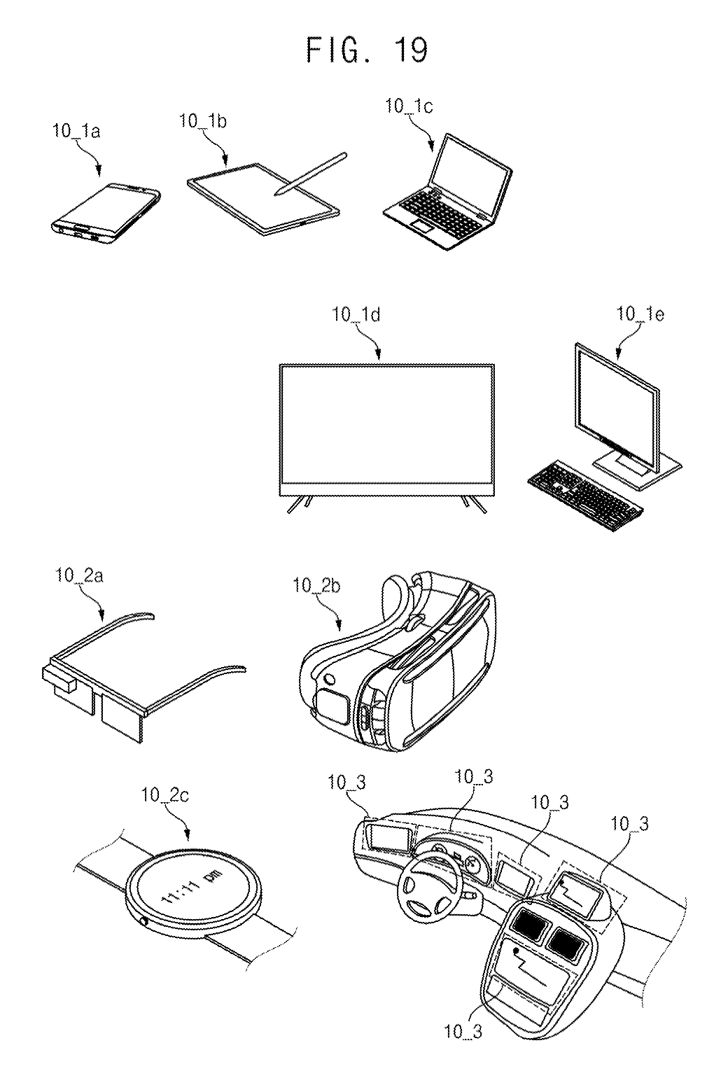

FIG. 19 is a schematic diagram illustrating the electronic device of FIG. 18.

Referring to FIG. 19, various electronic devices to which display devices according to embodiments are applied may include image display electronic devices such as a smart phone 10_1a, a tablet personal computer (PC) 10_1b, a laptop 10_1c, a television (TV) 10_1d, a desk monitor 10_1e, and the like, wearable electronic devices including display modules such as smart glasses 10_2a, a head-mounted display (HMD) 10_2b, a smart watch 10_2c, and the like, and vehicle electronic devices 10_3 including display modules such as an automobile’s instrument panel, a Center Information Display (CID) placed on center fascia and dashboard, a room mirror display, and the like.

Embodiments of the present disclosure may be applied to a display device and an electronic device including the display device. For example, embodiments of the present disclosure may be applied to a smart phone, a cellular phone, a smart pad, a smart watch, a tablet PC, a vehicle navigation system, a TV, a computer monitor, a laptop, and the like.

Although non-limiting example embodiments of the present disclosure have been described with reference to the accompanying drawings, it will be understood by those skilled in the art that various modifications and changes can be made to the example embodiments without departing from the spirit and scope of the present disclosure.

What is claimed is:

1. A display device comprising:
a first light-emitting layer on a substrate;
a second light-emitting layer on the substrate, and spaced apart from the first light-emitting layer in a first direction;
a first lens overlapping with the first light-emitting layer, on the first light-emitting layer, the first lens comprising a first radius of curvature; and
a second lens overlapping with the second light-emitting layer, on the second light-emitting layer, the second lens comprising a second radius of curvature that is smaller than the first radius of curvature.

2. The display device of claim 1, wherein a light-gathering efficiency of the second lens is greater than a light-gathering efficiency of the first lens.

3. The display device of claim 1, further comprising:
a third light-emitting layer on the substrate, and spaced apart from the second light-emitting layer in the first direction; and
a third lens overlapping with the third light-emitting layer, on the third light-emitting layer, the third lens comprising a third radius of curvature that is smaller than the second radius of curvature.

4. The display device of claim 1, further comprising:
a first light-blocking member adjacent to the first lens, the first light-blocking member comprising a first width in the first direction; and
a second light-blocking member adjacent to the second lens, the second light-blocking member comprising a second width in the first direction that is larger than the first width.

5. The display device of claim 4, further comprising:
a first lower light-blocking member overlapping with the first light-blocking member, underneath the first light-blocking member, the first lower light-blocking member comprising the first width; and
a second lower light-blocking member overlapping with the second light-blocking member, underneath the second light-blocking member, the second lower light-blocking member comprising the second width.

6. The display device of claim 1, wherein the first light-emitting layer is configured to emit a first light through the first lens, the first light comprising a first front light and a first side light,
wherein the second light-emitting layer is configured to emit a second light through the second lens, the second light comprising a second front light and a second side light,
wherein each of the first front light and the second front light is emitted in a direction perpendicular to the substrate,
wherein the first side light is emitted in a direction at an acute angle with respect to the direction perpendicular to the substrate,
wherein the second side light is emitted in the direction at the acute angle with respect to the direction perpendicular to the substrate, and
wherein a ratio of a luminance of the second side light to a luminance of the second front light is smaller than a ratio of a luminance of the first side light to a luminance of the first front light.

7. The display device of claim 6, further comprising:
a third light-emitting layer on the substrate, and spaced apart from the second light-emitting layer in the first direction; and
a third lens overlapping with the third light-emitting layer, on the third light-emitting layer, the third lens comprising a third radius of curvature that is smaller than the second radius of curvature,
wherein the third light-emitting layer is configured to emit a third light through the third lens, the third light comprising a third front light and a third side light, and
wherein a ratio of a luminance of the third side light to a luminance of the third front light is smaller than the ratio of the luminance of the second side light to the luminance of the second front light.

8. The display device of claim 1, further comprising:
a third light-emitting layer on the substrate and adjacent to the first light-emitting layer; and
a fourth light-emitting layer on the substrate and adjacent to the second light-emitting layer,
wherein no lens is on the third light-emitting layer, and
wherein no lens is on the fourth light-emitting layer.

9. A display device comprising:
a first light-emitting layer on a substrate;
a second light-emitting layer on the substrate, and spaced apart from the first light-emitting layer in a first direction;
a first light-blocking member on the first light-emitting layer;
a second light-blocking member on the second light-emitting layer; and
a second upper light-blocking member overlapping with the second light-blocking member, on the second light-blocking member,
wherein a number of light-blocking members vertically stacked on the first light-emitting layer is different from a number of light-blocking members vertically stacked on the second light-emitting layer.

10. The display device of claim 9, wherein no light-blocking member is on the first light-blocking member.

11. The display device of claim 10, wherein no light-blocking member is on the second upper light-blocking member.

12. The display device of claim 9, further comprising:
a third light-emitting layer on the substrate, and spaced apart from the second light-emitting layer in the first direction;
a third light-blocking member on the third light-emitting layer;
a third-first upper light-blocking member on the third light-blocking member; and
a third-second upper light-blocking member on the third-first upper light-blocking member,
wherein a number of light-blocking members vertically stacked on the third light-emitting layer is different from the number of light-blocking members vertically stacked on the first light-emitting layer and the number of light-blocking members vertically stacked on the second light-emitting layer.

13. The display device of claim 12, wherein no light-blocking member is on the third-second upper light-blocking member.

14. The display device of claim 9, wherein a width of the first light-blocking member, a width of the second light-blocking member, and a width of the second upper light-blocking member are equal to each other.

15. The display device of claim 9, wherein a width of the first light-blocking member is smaller than a width of the second light-blocking member.

16. The display device of claim 15, wherein a width of the second upper light-blocking member is equal to the width of the second light-blocking member.

17. A display device comprising:
a first light-emitting layer on a substrate;
a second light-emitting layer on the substrate, and spaced apart from the first light-emitting layer in a first direction;
a first light-blocking member on the first light-emitting layer and comprising a first width;
a second-first light-blocking member on the second light-emitting layer and comprising a second-first width; and
a second-second light-blocking member on the second light-emitting layer and between the first light-blocking member and the second-first light-blocking member, the second-second light-blocking member comprising a second-second width that is smaller than the second-first width.

18. The display device of claim 17, wherein the second-first width is larger than the first width.

19. The display device of claim 17, further comprising:
a third light-emitting layer on the substrate, and spaced apart from the first light-emitting layer in a second direction opposite to the first direction;
a third-first light-blocking member on the third light-emitting layer and comprising a third-first width; and
a third-second light-blocking member on the third light-emitting layer and between the first light-blocking member and the third-first light-blocking member, the third-second light-blocking member comprising a third-second width that is smaller than the third-first width.

20. An electronic device comprising:
the display device of claim 1; and
a power module configured to supply power to the display device.
